(19) United States
(12) Patent Application Publication
(10) Pub. No.: US 2022/0377947 A1
(43) Pub. Date: Nov. 24, 2022

(54) ACTIVE COOLING IN A MULTI-DEVICE WIRELESS CHARGER

(71) Applicant: AIRA, INC., Chandler, AZ (US)

(72) Inventors: Eric Heindel Goodchild, Phoenix, AZ (US); Simon McElrea, Phoenix, AZ (US); Aleksandar Petrovic, Phoenix, AZ (US)

(21) Appl. No.: 17/744,613

(22) Filed: May 13, 2022

Related U.S. Application Data
(60) Provisional application No. 63/189,222, filed on May 16, 2021.
(60) Provisional application No. 63/190,196, filed on May 18, 2021.

(51) Int. Cl. H05K 7/20; H02J 50/40; H02J 50/00

(52) U.S. Cl. CPC H05K 7/20909; H02J 50/402; H02J 50/005

(57) ABSTRACT

Systems, methods and apparatus for wireless charging are disclosed. A wireless charging device has a plurality of planar power transmitting coils, a driver circuit and at least one substrate having channels formed therein. The channels can receive a flow of air at a port of entry and conduct the flow of air through the substrate to a port of exit. The planar power transmitting coils may be supported by at least one substrate. Each planar power transmitting coil may be formed as a spiral winding surrounding a power transfer area. The driver circuit may be configured to provide a charging current to one or more of the planar power transmitting coils when a chargeable device is placed on or near the wireless charging device. The one or more channels may be configured to conduct the flow of air past or through the planar power transmitting coils and the driver circuit.

### PRIORITY CLAIM

This application claims priority to and the benefit of provisional patent application No. 63/189,222 filed in the United States Patent Office on 16 May 2021 and provisional patent application No. 63/190,196 filed in the United States Patent Office on May 18, 2021, and the entire content of these applications are incorporated herein by reference as if fully set forth below in its entirety and for all applicable purposes.

### TECHNICAL FIELD

The present invention relates generally to wireless charging of batteries, including batteries in mobile computing devices, and more particularly to removal of heat from a charging surface of a wireless charging device.

### BACKGROUND

Wireless charging systems have been deployed to enable certain types of devices to charge internal batteries without the use of a physical charging connection. Devices that can take advantage of wireless charging include mobile computing/processing devices and mobile communication devices. Standards, such as the Qi standard defined by the Wireless Power Consortium enable devices manufactured by a first supplier to be wirelessly charged using a charger manufactured by a second supplier. Standards for wireless charging are optimized for relatively simple configurations of devices and tend to provide basic charging capabilities.

Improvements in wireless charging capabilities are required to support continually increasing complexity of mobile devices and changing form factors and to support new uses of wireless charging devices. For example, there is a need for charging devices that provide higher power. There is also a need to control temperature in wireless charging systems, and to remove, dissipate or limit heat generated through losses and other inefficiencies arising from wireless charging systems.

### BRIEF DESCRIPTION OF THE DRAWINGS

FIG. 1 illustrates an example of a charging cell that may be employed to provide a charging surface of a wireless charging device in accordance with certain aspects disclosed herein.

FIG. 2 illustrates an example of an arrangement of charging cells provided on a single layer of a segment of a charging surface of a wireless charging device that may be adapted in accordance with certain aspects disclosed herein.

FIG. 3 illustrates an example of an arrangement of charging cells when multiple layers of charging cells are overlaid within a segment of a charging surface of a wireless charging device that may be adapted in accordance with certain aspects disclosed herein.

FIG. 4 illustrates the arrangement of power transfer areas provided by a charging surface of a charging device that employs multiple layers of charging cells configured in accordance with certain aspects disclosed herein.

FIG. 5 illustrates a wireless transmitter that may be provided in a charger base station in accordance with certain aspects disclosed herein.

FIG. 6 illustrates a first topology that supports matrix multiplexed switching for use in a wireless charging device adapted in accordance with certain aspects disclosed herein.

FIG. 7 illustrates a second topology that supports direct current drive in a wireless charging device adapted in accordance with certain aspects disclosed herein.

FIG. 8 illustrates a charging cell layout configured in accordance with certain aspects of this disclosure.

FIG. 9 illustrates an example of a Litz transmitting coil configured in accordance with certain aspects of this disclosure.

FIG. 10 illustrates an example of a portion of a charging surface provided multiple overlapping Litz coils in accordance with certain aspects of this disclosure.

FIG. 11 illustrates a charging surface of a wireless charging device constructed from

Litz coils in accordance with certain aspects of this disclosure.

FIG. 12 illustrates certain aspects of a Litz coil substrate provided in accordance with certain aspects of this disclosure.

FIG. 13 provides a cross-sectional view of a multi-coil free-positioning wireless charging device configured in accordance with certain aspects of this disclosure.

FIG. 14 illustrates certain aspects of a Litz coil substrate configured to remove heat in accordance with certain aspects of this disclosure.

FIG. 15 shows a first example of a system in which a wireless charging device is coupled to an airflow in accordance with certain aspects of this disclosure.

FIG. 16 shows a second example of a system in which a wireless charging device receives an airflow in accordance with certain aspects of this disclosure.

FIG. 17 shows an example of a third system in which a wireless charging device is coupled to an airflow in accordance with certain aspects of this disclosure.

FIG. 18 provides a view of a first side of a wireless charging device that can be cooled by a forced air flow produced by an external fan in accordance with certain aspects of this disclosure.

FIG. 19 provides a view of a second side of a wireless charging device that can be cooled by a forced air flow produced by an external fan in accordance with certain aspects of this disclosure.

FIG. 20 provides a view of a first side of a wireless charging device that can be cooled by a forced air flow produced by internal impeller fans in accordance with certain aspects of this disclosure.

FIG. 21 provides a view of a second side of a wireless charging device that can be cooled by a forced air flow produced by internal impeller fans in accordance with certain aspects of this disclosure.

FIG. 22 provides a side view of a multi-coil free-positioning wireless charging device that can be cooled by a forced airflow produced by a fan assembly located within a wireless charging device in accordance with certain aspects of this disclosure.

FIG. 23 illustrates an example of a multi-coil free-positioning wireless charging device that can be cooled by a forced airflow attachment in accordance with certain aspects of this disclosure.

FIG. 24 provides a reverse view of the wireless charging device illustrated in FIG. 23.

FIG. 25 provides a side view of the wireless charging device illustrated in FIG. 23.

FIG. 26 illustrates cooling of a multi-coil free-positioning wireless charging device by a hybrid forced airflow in accordance with certain aspects of this disclosure.

FIG. 27 illustrates one example of an apparatus employing a processing circuit that may be adapted according to certain aspects disclosed herein.

FIG. 28 illustrates a method for configuring a charging device in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of wireless charging systems will now be presented with reference to various apparatus and methods. These apparatus and methods will be described in the following detailed description and illustrated in the accompanying drawing by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a processor-readable storage medium. A processor-readable storage medium, which may also be referred to herein as a computer-readable medium may include, by way of example, a magnetic storage device (e.g., hard disk, floppy disk, magnetic strip), an optical disk (e.g., compact disk (CD), digital versatile disk (DVD)), a smart card, a flash memory device (e.g., card, stick, key drive), Near Field Communications (NFC) token, random access memory (RAM), read only memory (ROM), programmable ROM (PROM), erasable PROM (EPROM), electrically erasable PROM (EEPROM), a register, a removable disk, a carrier wave, a transmission line, and any other suitable medium for storing or transmitting software. The computer-readable medium may be resident in the processing system, external to the processing system, or distributed across multiple entities including the processing system. Computer-readable medium may be embodied in a computer-program product. By way of example, a computer-program product may include a computer-readable medium in packaging materials. Those skilled in the art will recognize how best to implement the described functionality presented throughout this disclosure depending on the particular application and the overall design constraints imposed on the overall system.

### Overview

Certain aspects of the present disclosure relate to systems, apparatus and methods associated with wireless charging devices that provide a free-positioning charging surface using multiple transmitting coils, including wireless charging devices that can concurrently charge multiple receiving devices. In one aspect, a controller in the wireless charging device can locate a device to be charged and can configure one or more transmitting coils optimally positioned to deliver power to the receiving device. Charging cells may be provisioned or configured with one or more inductive transmitting coils and multiple charging cells may be arranged or configured to provide the charging surface. The location of a device to be charged may be detected through sensing techniques that associate location of the device with changes in a physical characteristic centered at a known location on the charging surface. In some examples, sensing of location may be implemented using capacitive, resistive, inductive, touch, pressure, load, strain, and/or another appropriate type of sensing.

In one aspect of the disclosure, each charging cell in a plurality of charging cells may be constructed using Litz wire to form a planar or substantially flat winding that provides a Litz coil with a central power transfer area. Each charging cell may include or be associated with multiple Litz coils that have coaxial or overlapping power transfer areas. The plurality of charging cells may be arranged adjacent to the charging surface of the charging device without overlap of the charging cells.

In one example, a wireless charging device has at least one substrate with one or more channels formed therein. The one or more channels may be configured to receive a flow of air at a port of entry and to conduct the flow of air through the substrate to a port of exit. The wireless charging device has a plurality of planar power transmitting coils supported by the at least one substrate. Each planar power transmitting coil may be formed as a spiral winding surrounding a power transfer area. The wireless charging device has a driver circuit configured to provide a charging current to one or more of the plurality of planar power transmitting coils when a chargeable device is placed on or near the wireless charging device. The one or more channels may be configured to conduct the flow of air past or through the plurality of planar power transmitting coils and the driver circuit.

### Charging Cells

Certain aspects of the present disclosure relate to systems, apparatus and methods applicable to wireless charging devices that provide a free-positioning charging surface that has multiple transmitting coils or that can concurrently charge multiple receiving devices. In one aspect, a controller in the wireless charging device can locate a device to be charged and can configure one or more transmitting coils optimally positioned to deliver power to the receiving device. Charging cells may be provisioned or configured with one or more inductive transmitting coils and multiple charging cells may be arranged or configured to provide the charging surface. The location of a device to be charged may be detected through sensing techniques that associate location of the device to changes in a physical characteristic centered at a known location on the charging surface. In some examples, sensing of location may be implemented using capacitive, resistive.

According to certain aspects disclosed herein, a charging surface in a wireless charging device may be provided using charging cells that are deployed adjacent to a surface of the charging device. In one example the charging cells are deployed in accordance with a honeycomb packaging configuration in one or more layers below or adjacent to the charging surface. A charging cell may be implemented in a wireless charging device using one or more coils that can each induce a magnetic field along an axis that is substantially orthogonal to the charging surface, adjacent to the coil. In this description, a charging cell may refer to an element having one or more coils where each coil is configured to produce an electromagnetic field that is additive with respect to the fields produced by other coils in the charging cell and directed along or proximate to a common axis. In this disclosure, a coil in a charging cell may be referred to as a charging coil, a transmitting coil, a Litz coil or using some combination of these terms.

In some implementations, a charging cell includes coils that are stacked along a common axis and/or that overlap such that they contribute to the magnetic field that is induced substantially orthogonal to the surface of the charging device. In some implementations, a charging cell includes coils that are arranged within a defined portion of the surface of the charging device and that contribute to an induced magnetic field within the defined portion of the charging surface, the magnetic field contributing to a magnetic flux flowing substantially orthogonal to the charging surface.

In some implementations, charging cells may be configurable by providing an activating current to coils that are included in one or more dynamically-defined charging cells. For example, a wireless charging device may include multiple stacks of coils deployed across a charging surface, and the wireless charging device may detect the location of a device to be charged based on proximity to one or more stacks of coils. The charging device may select some combination of the stacks of coils to define or provide a charging cell adjacent to the device to be charged. In some instances, a charging cell may include, or be characterized as a single coil. However, it should be appreciated that a charging cell may include multiple stacked coils and/or multiple adjacent coils or stacks of coils. The coils may be referred to herein as charging coils, wireless charging coils, transmitter coils, transmitting coils, power transmitting coils, power transmitter coils, or the like.

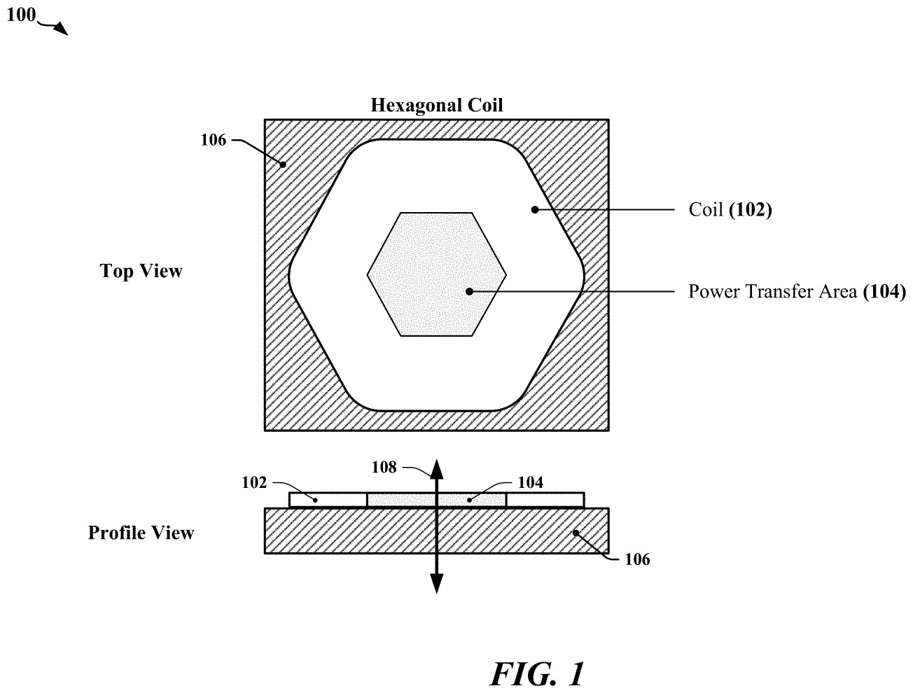

FIG. 1 illustrates an example of a charging cell 100 that may be deployed and/or configured to provide a charging surface of a wireless charging device. In this disclosure, a charging surface may be understood to include an array of charging cells 100 provided on one or more substrates 106 of a printed circuit board, or an array of charging coils embedded in a structure formed from one or more substrates 106. A circuit comprising one or more integrated circuits (ICs) and/or discrete electronic components may be provided on one or more of the substrates 106. The circuit may include drivers and switches used to control currents provided to coils used to transmit power to a receiving device. The circuit may be implemented using a processing circuit that includes one or more processors and/or one or more controllers that can be configured to perform certain functions disclosed herein. In some instances, some or all of the processing circuit may be provided external to the charging device. In some instances, a power supply may be coupled to the charging device.

The charging cell 100 may be provided in close proximity to an outer surface area of the charging device, upon which one or more devices can be placed for charging. The charging device may include multiple instances of the charging cell 100. In one example, the charging cell 100 has a substantially hexagonal shape that delimits or encloses one or more coils 102. Each coil may be constructed using conductors, wires or circuit board traces that can receive a current sufficient to produce an electromagnetic field in a power transfer area 104. In various implementations, some coils 102 can have an overall shape that is substantially polygonal, including the hexagonal charging cell 100 illustrated in FIG. 1. In some implementations, one or more coils may have a flat spiral shape or a shape that is substantially circular. Other implementations provide coils 102 that are circular or elliptical in form or that have some other shape. The shape of the coils 102 may be determined at least in part by the number of windings in each coil, capabilities or limitations of fabrication technology, and/or to optimize layout of the charging cells on a substrate 106 such as a printed circuit board substrate. Each coil 102 may be implemented using wires, printed circuit board traces and/or other connectors in a spiral configuration. Each charging cell 100 may span two or more layers separated by an insulator or substrate 106 such that coils 102 in different layers are centered around a common axis 108.

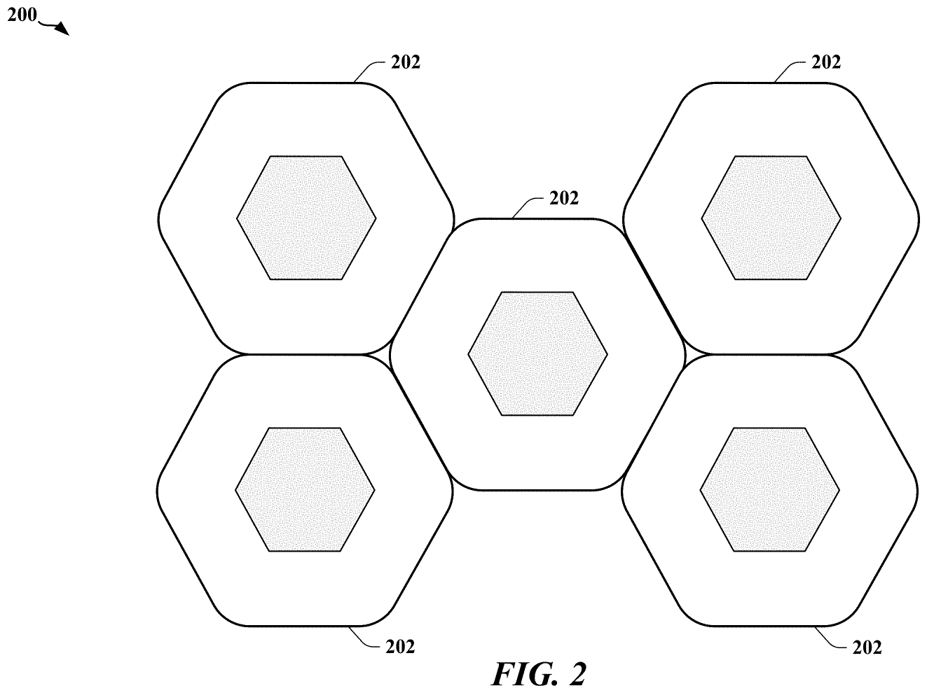

FIG. 2 illustrates an example of an arrangement 200 of charging cells 202 provided on a single layer of a segment or portion of a charging surface that may be included in a charging system that has been adapted in accordance with certain aspects disclosed herein. The charging cells 202 are arranged according to a honeycomb packaging configuration. In this example, the charging cells 202 are arranged end-to-end without overlap. This arrangement can be provided without through-holes or wire interconnects. Other arrangements are possible, including arrangements in which some portion of the charging cells 202 overlap. For example, wires of two or more coils may be interleaved, arranged concentrically or overlaid to some extent.

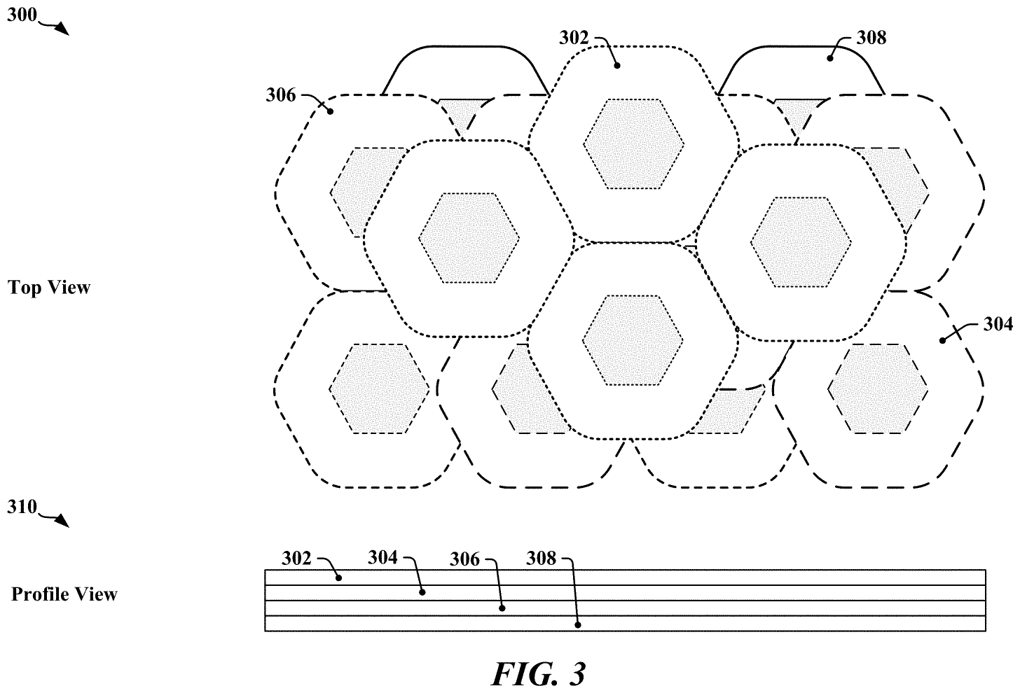

FIG. 3 illustrates an example of an arrangement of charging cells from two perspectives 300, 310 when multiple layers are overlaid within a segment or portion of a charging surface that may be adapted in accordance with certain aspects disclosed herein. In this example, four layers of charging cells 302, 304, 306, 308 are provided within the charging surface. The charging cells within each layer of charging cells 302, 304, 306, 308 are arranged according to a honeycomb packaging configuration. In one example, the layers of charging cells 302, 304, 306, 308 may be formed on a printed circuit board that has four or more copper layers. The arrangement of charging cells 100 can be selected to provide complete coverage of a designated charging area that is adjacent to the illustrated segment.

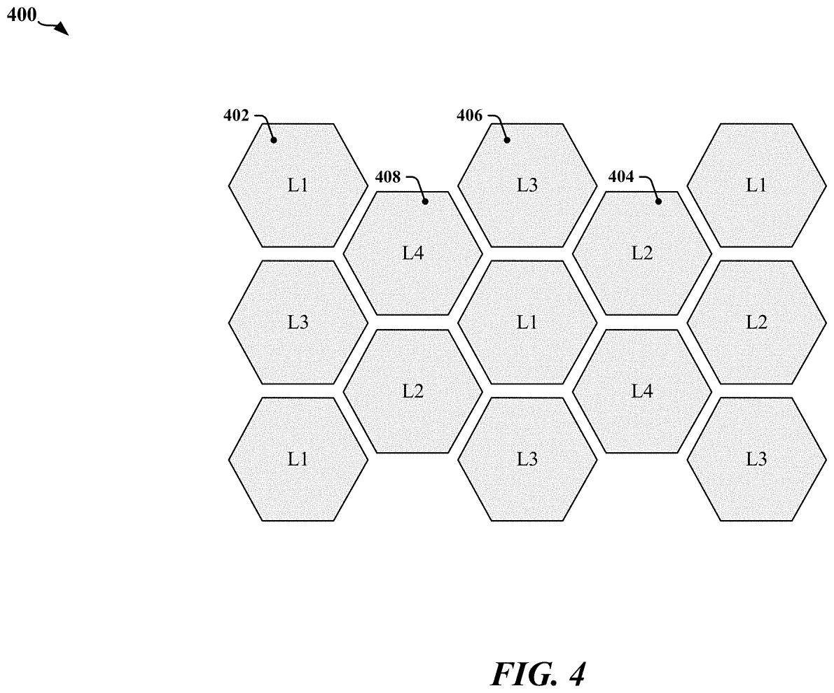

FIG. 4 illustrates the arrangement of power transfer areas defined or configured in a charging surface 400 provided by a charging system in accordance with certain aspects disclosed herein. The illustrated charging surface 400 is constructed using four layers of charging cells 402, 404, 406, 408. In FIG. 4, each power transfer area provided by a charging cell in the first layer of charging cells 402 is marked “L1”, each power transfer area provided by a charging cell in the second layer of charging cells 404 is marked “L2”, each power transfer area provided by a charging cell in the third layer of charging cells 406 is marked “L3”, and each power transfer area provided by a charging cell in the fourth layer of charging cells 408 is marked “L4”.

### Wireless Transmitter

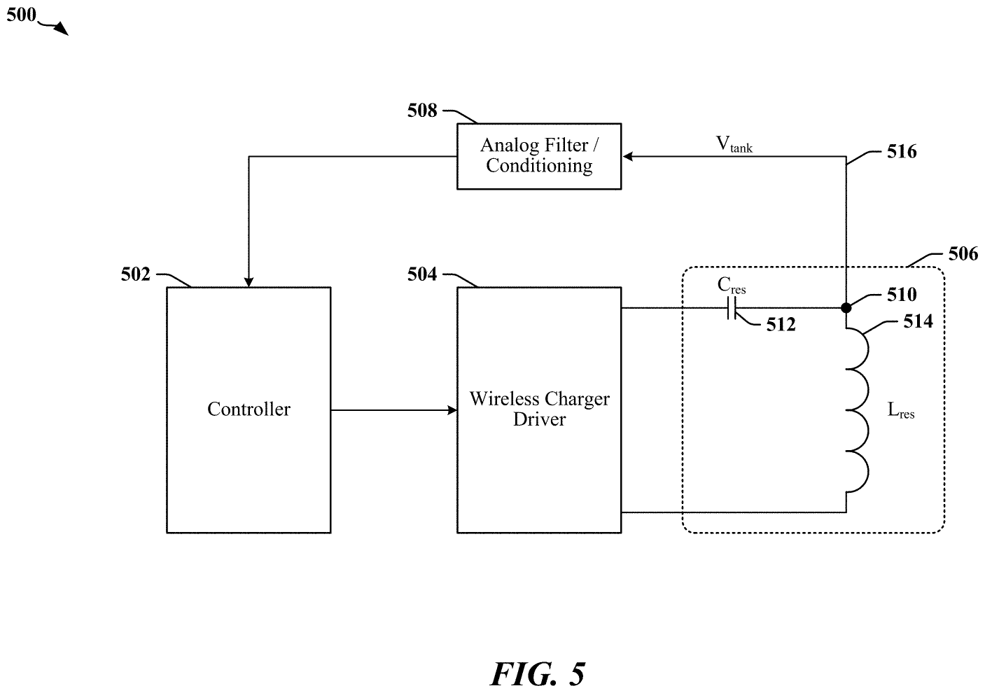

FIG. 5 illustrates certain aspects of a wireless transmitter 500 that can be provided in a base station of a wireless charging device. A base station in a wireless charging device may include one or more processing circuits used to control operations of the wireless charging device. A controller 502 may receive a feedback signal filtered or otherwise processed by a filter circuit 508. The controller may control the operation of a driver circuit 504 that provides an alternating current to a resonant circuit 506. In some examples, the controller 502 generates a digital frequency reference signal used to control the frequency of the alternating current output by the driver circuit 504. In some instances, the digital frequency reference signal may be generated using a programmable counter or the like. In some examples, the driver circuit 504 includes a power inverter circuit and one or more power amplifiers that cooperate to generate the alternating current from a direct current source or input. In some examples, the digital frequency reference signal may be generated by the driver circuit 504 or by another circuit. The resonant circuit 506 includes a capacitor 512 and inductor 514. The inductor 514 may represent or include one or more transmitting coils in a charging cell that produce a magnetic flux responsive to the alternating current. The resonant circuit 506 may also be referred to herein as a tank circuit, LC tank circuit, or LC tank, and the voltage 516 measured at an LC node 510 of the resonant circuit 506 may be referred to as the tank voltage.

Passive ping techniques may use the voltage and/or current measured or observed at the LC node 510 to identify the presence of a receiving coil in proximity to the charging pad of a device adapted in accordance with certain aspects disclosed herein. Some conventional wireless charging devices include circuits that measure voltage at the LC node 510 of the resonant circuit 506 or the current in the resonant circuit 506. These voltages and currents may be monitored for power regulation purposes and/or to support communication between devices. According to certain aspects of this disclosure, voltage at the LC node 510 in the wireless transmitter 500 illustrated in FIG. 5 may be monitored to support passive ping techniques that can detect presence of a chargeable device or other object based on response of the resonant circuit 506 to a short burst of energy (the ping) transmitted through the resonant circuit 506.

A passive ping discovery technique may be used to provide fast, low-power discovery. A passive ping may be produced by driving a low-energy, fast pulse through a network that includes the resonant circuit 506 with a fast pulse that includes a small amount of energy. The fast pulse excites the resonant circuit 506 and causes the network to oscillate at its natural resonant frequency until the injected energy decays and is dissipated. The response of a resonant circuit 506 to a fast pulse may be determined in part by the resonant frequency of the resonant LC circuit. A response of the resonant circuit 506 to a passive ping that has initial voltage (V₀) may be represented by the voltage V_{LC} observed at the LC node 510, such that:

$${V}_{L C} = {V}_{0} {e}^{- ( \frac{ω}{2 Q} ) t} \qquad ( Eq . 1 )$$

Voltage or current in the resonant circuit 506 may be monitored when the controller 502 or another processor is using digital pings to detect presence of objects. A digital ping is produced by driving the resonant circuit 506 for a period of time. The resonant circuit 506 is a tuned network that includes a transmitting coil of the wireless charging device. A receiving device may modulate the voltage or current observed in the resonant circuit 506 by modifying the impedance presented by its power receiving circuit in accordance with signaling state of a modulating signal. The controller 502 or other processor then waits for a data modulated response that indicates that a receiving device is nearby.

### Selectively Activating Coils

According to certain aspects disclosed herein, power transmitting coils in one or more charging cells may be selectively activated to provide an optimal electromagnetic field for charging a compatible device. In some instances, power transmitting coils may be assigned to charging cells, and some charging cells may overlap other charging cells. The optimal charging configuration may be selected at the charging cell level. In some examples, a charging configuration may include charging cells in a charging surface that are determined to be aligned with or located close to the device to be charged. A controller may activate a single power transmitting coil or a combination of power transmitting coils based on the charging configuration which in turn is based on detection of location of the device to be charged. In some implementations, a wireless charging device may have a driver circuit that can selectively activate one or more power transmitting coils or one or more predefined charging cells during a charging event.

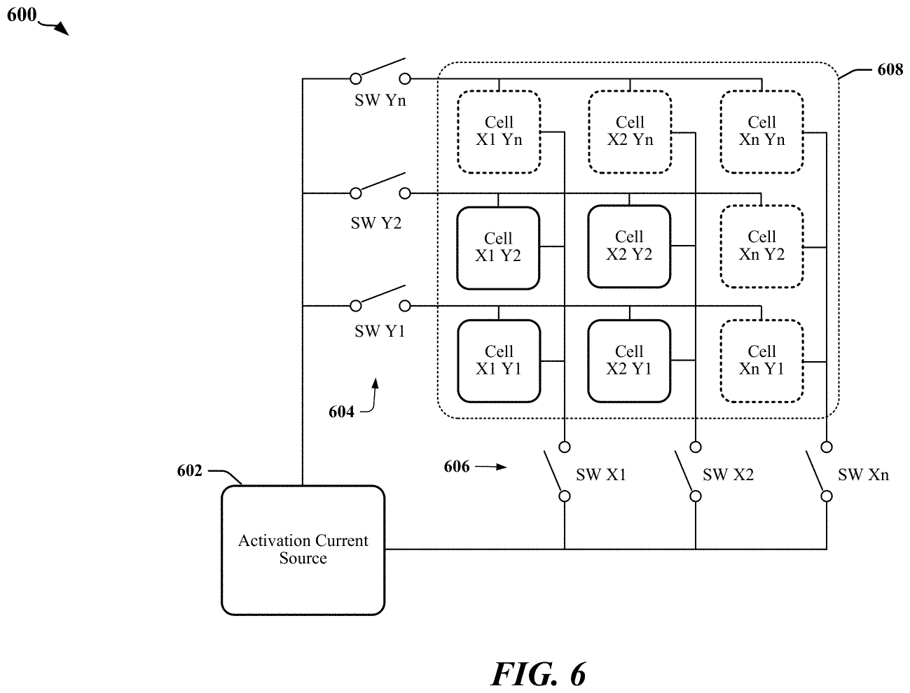

FIG. 6 illustrates a first topology 600 that supports matrix multiplexed switching for use in a wireless charging device adapted in accordance with certain aspects disclosed herein. The wireless charging device may select one or more charging cells 100 to charge a receiving device. Charging cells 100 that are not in use can be disconnected from current flow. A relatively large number of charging cells 100 may be used in the honeycomb packaging configuration illustrated in FIGS. 2 and 3, requiring a corresponding number of switches. According to certain aspects disclosed herein, the charging cells 100 may be logically arranged in a matrix 608 having multiple cells connected to two or more switches that enable specific cells to be powered. In the illustrated first topology 600, a two-dimensional matrix 608 is provided, where the dimensions may be represented by X and Y coordinates. Each of a first set of switches 606 is configured to selectively couple a first terminal of each cell in a column of cells to a first terminal of a voltage or current source 602 that provides current to activate coils in one or more charging cells during wireless charging. Each of a second set of switches 604 is configured to selectively couple a second terminal of each cell in a row of cells to a second terminal of the voltage or current source 602. A charging cell is active when both terminals of the cell are coupled to the voltage or current source 602.

The use of a matrix 608 can significantly reduce the number of switching components needed to operate a network of tuned LC circuits. For example, N individually connected cells require at least N switches, whereas a two-dimensional matrix 608 having N cells can be operated with √N switches. The use of a matrix 608 can produce significant cost savings and reduce circuit and/or layout complexity. In one example, a 9-cell implementation can be implemented in a 3×3 matrix 608 using 6 switches, saving 3 switches. In another example, a 16-cell implementation can be implemented in a 4×4 matrix 608 using 8 switches, saving 8 switches.

During operation, at least 2 switches are closed to actively couple one coil or charging cell to the voltage or current source 602. Multiple switches can be closed at once in order to facilitate connection of multiple coils or charging cells to the voltage or current source 602. Multiple switches may be closed, for example, to enable modes of operation that drive multiple transmitting coils when transferring power to a receiving device.

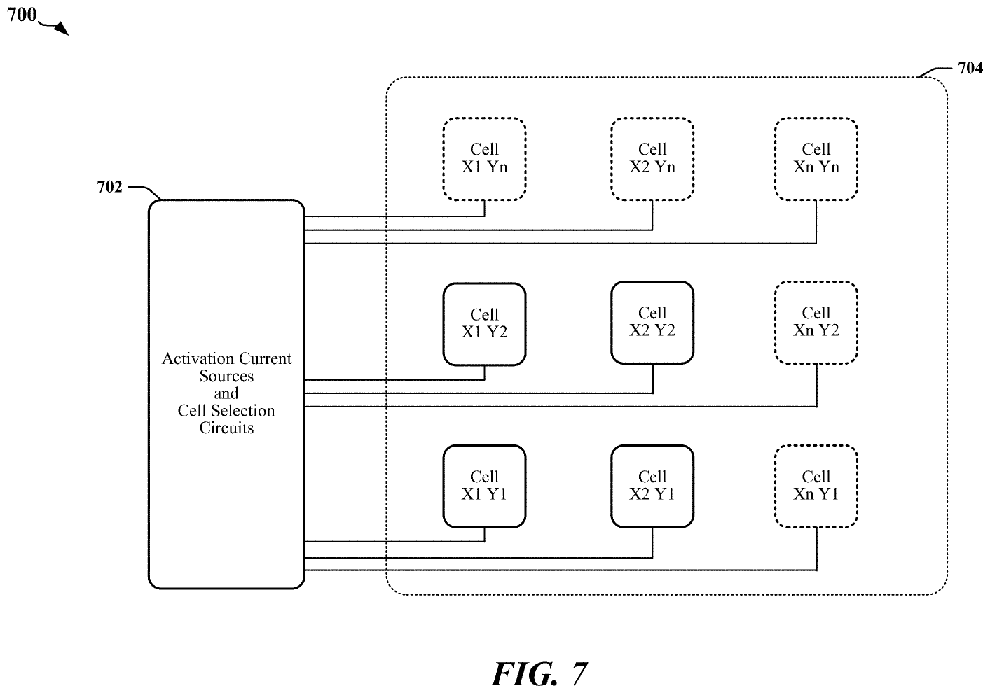

FIG. 7 illustrates a second topology 700 in which each individual coil or charging cell is directly driven by a driver circuit 702 in accordance with certain aspects disclosed herein. The driver circuit 702 may be configured to select one or more coils or charging cells 100 from a group of coils 704 to charge a receiving device. It will be appreciated that the concepts disclosed here in relation to charging cells 100 may be applied to selective activation of individual coils or stacks of coils. Charging cells 100 that are not in use receive no current flow. A relatively large number of charging cells 100 may be in use and a switching matrix may be employed to drive individual coils or groups of coils. In one example, a first switching matrix may configure connections that define a charging cell or group of coils to be used during a charging event and a second switching matrix may be used to activate the charging cell and/or group of selected coils.

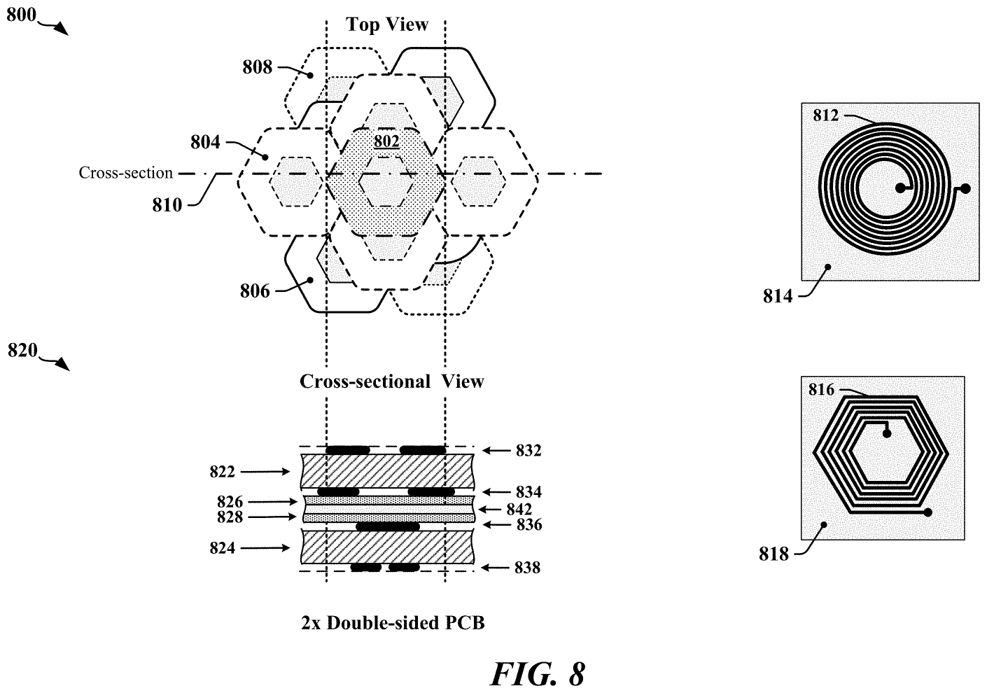

FIG. 8 illustrates a charging cell layout 800 configured in accordance with certain aspects of this disclosure. In the illustrated example, the charging cell layout 800 is provided using a four-layer structure implemented on the metal layers of a pair of two-layer printed circuit boards (PCBs) 822 or 824 that are bonded or joined by an insulating adhesive layer 826. In other examples, the four-layer structure may be implemented on the metal layers of a single four-layer printed circuit board (PCB). In the illustrated example, an active charging cell 802 is provided on a first layer of a four-layer structure and charging cells 804, 806, 808 provided on the other three layers may have windings that overlap the windings of the active charging cell 802. In one example, each charging cell includes a transmitting coil that has a winding formed as a decreasing radius trace 812 or 816 on one side of a PCB 822 or 824, with the winding being concentric with and/or surrounding a power transfer area (see FIG. 1). In one example, the decreasing radius trace 812 has a substantially smooth curved spiral shape. In another example, the decreasing radius trace 816 is segmented and generally hexagonal in shape. The decreasing radius traces 812 and 816 may be provided adjacent a magnetic core material 814 and 818, respectively. The magnetic core material 814 and 818 may be formed from a low coercivity material such as a soft ferrite. In one example, the magnetic core material 814 and 818 is integrated in an adhesive layer. In another example, the magnetic core material 814 and 818 may be attached to an adhesive layer or sandwiched between adhesive layers.

A partial view 820 of a lateral cross-section 810 of the two-layer PCBs 822 or 824 illustrates further aspects of charging cell layout 800. In some examples, a charging cell 804 in the second layer, a charging cell 806 in the third layer and a charging cell 808 in the second layer partially overlap the active charging cell 802. Areas of the metal layers 832, 834, 836 and 838 occupied by windings are shown in solid black, with individual traces not being explicitly shown. Each of the metal layers 832, 834, 836 and 838 is provided on a side of a PCB 822 or 824. A planar magnetic core 842 is provided between the two adjacent metal layers 834 and 836 of the PCBs 822 and 824. The planar magnetic core 842 may be included in an adhesive layer or between adhesive layers 826, 828. The planar magnetic core 842 and the adhesive layers 826, 828 are electrically non-conductive.

Certain challenges are associated with single-coil and multi-coil wireless charging systems that employ transmitting coils formed on PCBs. These challenges can include inefficient power delivery due to the current carrying capabilities of traces that form or supply the transmitting coils, skin effects, eddy currents induced from adjacent windings, and other electromagnetic issues. Skin effect losses occur in traces or wires carrying high frequency signals where the current tends to flow at outermost reaches (skin) of the trace or wire. The concentration of current in the skin of the trace or wire can effectively increase resistance of the trace or wire due to a reduction in the percentage of cross-sectional area of the trace or wire that is used to carry high-frequency AC current. Increasing demands for higher rates of power transfer in wireless charging devices can be at least partially met by improving the efficiency of power transmission through the transmitting coils of a wireless charging device. Earlier generations of receiving devices may demand up to 5 W maximum from the transmitter, while later generations of receiving devices can demand 15 W or more to expedite the charging process. Losses associated with increased power transmission levels often manifest in increased thermal generation and charging devices that supply power at high levels are generally required to dissipate heat efficiently or throttle power transmissions as heat builds in the charging device or the power receiving device.

Certain aspects of this disclosure enable wireless charging devices to improve the efficiency of wireless power transfers to receiving devices while mitigating thermal issues. Transmitted power may be increased through improvements to transmitting coil design and associated manufacturing techniques. In one aspect of this disclosure, transmitting coils may be formed from multi-stranded wires that exhibit reduced losses and can thereby reduce heat generation during power transmission. A wireless charging device may employ multiple wire-formed transmitting coils that can be assembled and maintained in alignment using a substrate that receives and maintains the coils in preassigned three-dimensional (3D) locations.

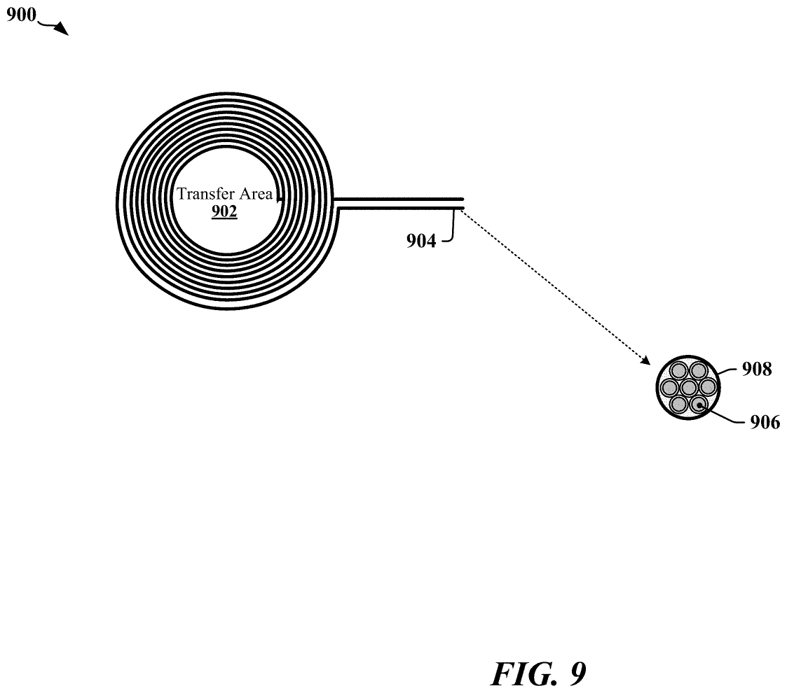

FIG. 9 illustrates an example of a transmitting coil configured in accordance with certain aspects of this disclosure. The transmitting coil may be wound from a multi-stranded Litz wire 904 and may be referred to as a Litz coil 900. Each strand 906 of the Litz wire 904 is formed as an insulated conductor that is sufficiently thin to mitigate or substantially reduce skin effect loss. Skin effect losses occur in wires carrying high frequency signals where the current tends to flow at outermost reaches (skin) of the wire. The strands 906 in the Litz wire 904 are insulated to maintain their individual nature and are twisted such that the relative positioning of the individual strands 906 changes over the length of the Litz wire 904. In some instances, the strands 906 are bound by an exterior insulating layer 908. The Litz coil 900 is wound as a substantially planar coil with an open interior that corresponds to the power transfer area 902.

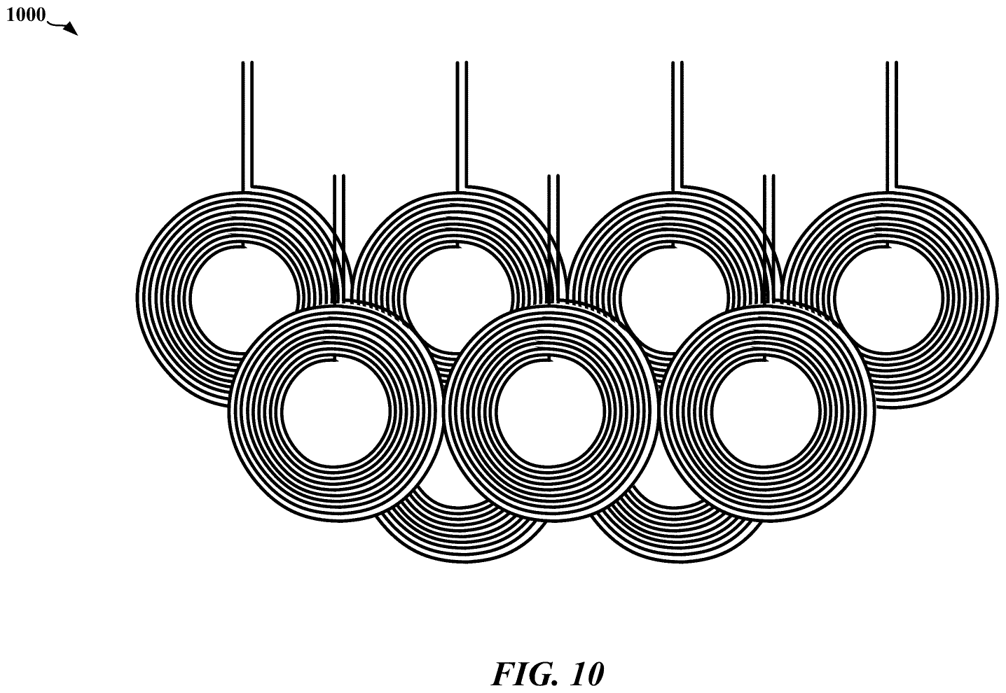

FIG. 10 illustrates an example of a portion of a charging surface 1000 provided by multiple overlapping Litz coils 900. In the illustrated example, the charging surface 1000 is constructed using three layers of Litz coils 900, although the number of layers of Litz coils 900 and arrangement of the Litz coils 900 in the charging surface 1000 may vary according to application, size of the charging surface 1000 and power transfer requirements per Litz coil 900.

The configuration of Litz coils 900 in a charging surface 1000 may be precisely defined by design requirements. The number of Litz coils 900 to be assembled may be difficult to manage and align and variability in positioning of the Litz coils 900 can result in imprecise configurations of coils in some finished devices. In some instances, the Litz coils 900 may be retained in position using an adhesive or epoxy resin. However, the Litz coils 900 must be accurately positioned before application of the adhesive or resin and movement caused during application of the adhesive or resin may affect the operation of the finished wireless charging device. According to certain aspects of this disclosure, a substrate is provided to receive the Litz coils 900 and the substrate may be configured to maintain the Litz coils 900 in a desired configuration for the lifetime of the wireless charging device.

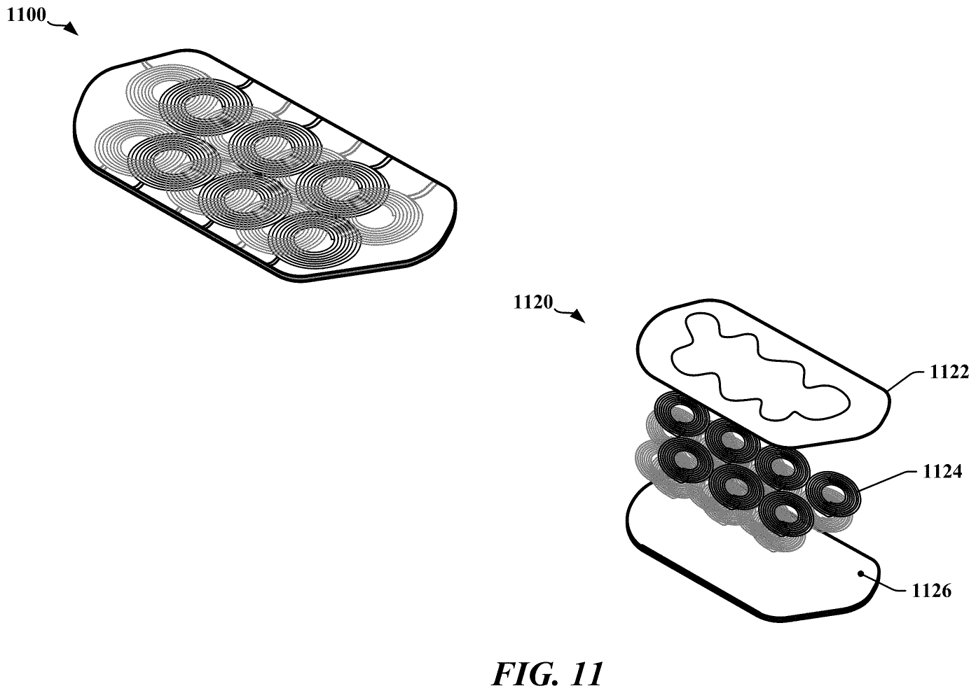

FIG. 11 provides a transparent view 1100 of Litz coils maintained within a Litz coil substrate used to provide a charging surface of a wireless charging device in accordance with certain aspects of this disclosure. The exploded view 1120 shows a Litz coil substrate 1122 configured to receive Litz coils and maintain the Litz coils in a predefined multi-layer Litz coil structure 1124 with 3D displacements between coils that meet tolerances defined by a designer. The Litz coil substrate 1122 may also define the spatial relationship between the multi-layer Litz coil structure 1124 and a ferrite layer 1126 or another type of magnetic half-core.

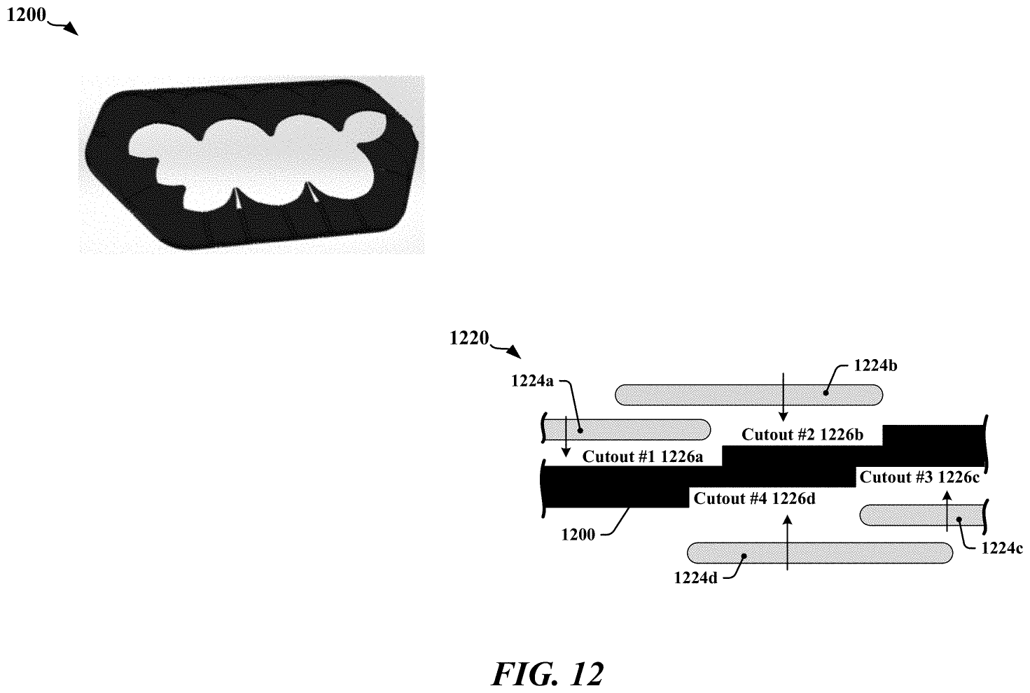

FIG. 12 illustrates certain aspects of a Litz coil substrate 1200 provided in accordance with certain aspects of this disclosure. The Litz coil substrate 1200 may be formed from a polymer, acetate, vinyl, nitrile rubber, latex, extruded polystyrene foam and/or another type of material. The Litz coil substrate 1200 can have multiple cutouts that enable the Litz coils 900 to be placed in position in an ordered assembly. In some examples, the cutouts may be formed during manufacture when the Litz coil substrate 1200 is fabricated by 3D printing, molding, extrusion and/or low-pressure expansion. In some examples, the cut-outs may be provided by milling, grinding, etching, abrading, chemical erosion, chemical dissolution or by another technique suitable for use with the material used to form the Litz coil substrate 1200.

Certain aspects of the Litz coil substrate 1200 are illustrated in a cross-sectional view 1220. The illustrated Litz coil substrate 1200 provides a four-layer charging surface and the cross-sectional view 1220 illustrates an example of placement and assembly of four Litz coils 1224a-1224d. The Litz coil substrate 1200 has a deep, first cutout 1226a in the Litz coil substrate 1200 that receives a first Litz coil 1224a. This first cutout 1226a may be formed as a complete circle in some examples. In other examples, the first cutout 1226a may overlap with another cutout in the same plane of the Litz coil substrate 1200.

When the first Litz coil 1224a has been secured within the first cutout 1226a, a second Litz coil 1224b may be placed in a second cutout 1226b in the Litz coil substrate 1200. When in position within the Litz coil substrate 1200, the second Litz coil 1224b lies in a plane above the plane that includes the first Litz coil 1224a. A portion of the second Litz coil 1224b overlaps a portion of the first Litz coil 1224a. The separation of the planes that include the horizontal center lines of the first Litz coil 1224a and the second Litz coil 1224b may be configured or defined based on the relative difference in depths of the first cutout 1226a and the second cutout 1226b.

The third Litz coil 1224c is received by a deep, third cutout 1226c in the Litz coil substrate 1200. This third cutout 1226c may be formed as a complete circle in some examples. In other examples, the third cutout 1226c may overlap with another cutout in the same plane. In one example, the third cutout 1226c may partially overlap the first cutout 1226a resulting in a through-hole, when the bottom surface of the first Litz coil 1224a is in the same plane as the top surface or some other portion of the third Litz coil 1224c.

When the third Litz coil 1224c has been secured within the third cutout 1226c, a fourth Litz coil 1224d may be placed in a fourth cutout 1226d. The fourth Litz coil 1224d lies in a plane below the plane that includes the third Litz coil 1224c. A portion of the fourth Litz coil 1224d overlaps a portion of the third Litz coil 1224c when secured within the Litz coil substrate 1200. The separation of the planes that include the horizontal center lines of the third Litz coil 1224c and the fourth Litz coil 1224d may be configured by the relative difference in depths of the third cutout 1226c and the fourth cutout 1226d.

The Litz coil 1224a-1224d may be secured within the Litz coil substrate 1200 through a pressure fit, including when the Litz coil substrate 1200 is manufactured from a foam material. In some examples, the Litz coil 1224a-1224d may be secured within the Litz coil substrate 1200 by adhesive. In some examples, the Litz coil 1224a-1224d may be secured within the Litz coil substrate 1200 by mechanical means.

Certain aspects of this disclosure provide techniques for mitigating thermal issues in wireless charging devices, including wireless charging devices that employ Litz coils. A wireless charging system adapted in accordance with certain aspects of this disclosure can exhibit improved efficiencies in power usage over conventional systems. The improvements in efficiency obtained from the use of Litz coils and other mechanical and electromagnetic design techniques may be offset or limited by other inefficiencies in the wireless charging system that cause heat generation in the wireless charging system. In some instances, overall efficiency of a wireless charging system may not exceed 50% in some use cases. Inefficiencies can arise from losses due to eddy currents induced in packaging, PCBs, interconnects, fasteners and in circuit boards. Inefficiencies can arise in voltage conversion circuits. Conventional thermal management systems typically control heat generation by selectively reducing power transmissions when increases in temperature are detected. Unmitigated heat induced in the transmitting coils, driver circuits and housings of the wireless charging device and in the receiving coil, receiving circuits and casing of device being charged can limit the power transfer levels available to the wireless charging system. Inadequate thermal management can increase the time to charge a device when power transmissions are throttled to avoid excessive heat accumulation. The effects of inadequate thermal management can be perceived as a performance issue of the wireless charging system.

According to certain aspects of this disclosure, a wireless charging system may be configured to receive a flow of cooling fluid and to direct the flow to heat accumulating elements and surfaces of the wireless charging device and, in some instances, to a surface of a device being charged. Cooled or forced air may be used as the cooling fluid. In some examples, an airflow may be forced by a fan, bladeless fan or electrostatic blower. In some examples, the airflow may be passed through or received from an air conditioning system.

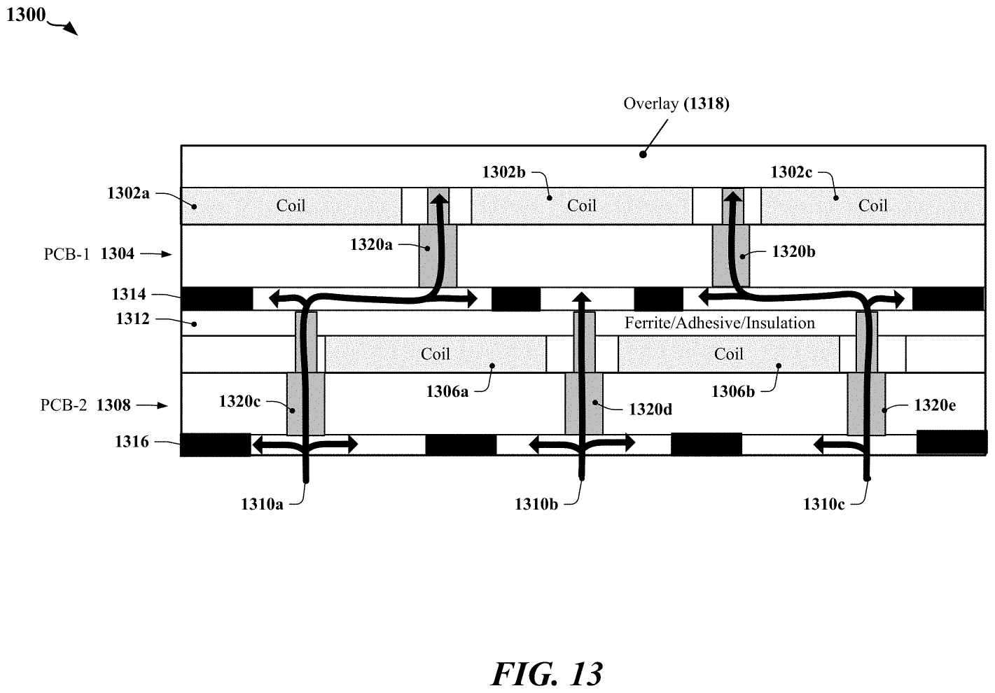

FIG. 13 is a cross-sectional view that illustrates an example of a multi-coil free-positioning wireless charging device 1300 configured in accordance with certain aspects of this disclosure. The wireless charging device 1300 may be adapted to receive and conduct an airflow through certain structures, cavities, layers, substrates and/or circuits in the wireless charging device 1300. In the illustrated example, a first two-layer PCB 1304 provides transmitting coils 1302a, 1302b, 1302c arranged across a top layer of the first two-layer PCB 1304. A second two-layer PCB 1308 provides transmitting coils 1306a, 1306b, arranged across a top layer of the second two-layer PCB 1308. The example of a two PCB implementation is used herein to facilitate description of certain cooling techniques but other combinations and configurations of PCBs may be employed in various implementations. In other examples instances, transmitting coils may be provided on top and bottom layers of the first two-layer PCB 1304 and/or the second two-layer PCB 1308.

The top layer of the first two-layer PCB 1304 may be configured to provide a charging surface of the wireless charging device 1300. For example, the top layer of the first two-layer PCB 1304 may be coated with a conformal coating or other overlay 1318. The PCBs 1304, 1308 may be mechanically coupled or may be joined using one or more adhesive layers 1312 and a spacer layer 1314. A spacer layer 1316 is also shown at the bottom of the second PCB 1308.

In some implementations, the adhesive layer 1312 may be multi-layered or multifaceted. In one example, the adhesive layer 1312 is a compound layer that includes a ferrite layer, an electrical insulating layer and/or a thermally insulating layer. In one example, the adhesive layer 1312 is a compound layer that provides partial ferrite or insulating layers located based on the position of one or more transmitting coils 1302a, 1302b, 1302c, 1306a, 1306b.

Horizontal ducts (referred to herein as channels) may be formed or fabricated within the spacer layers 1314, 1316. In some instances, the channels are configured to interconnect with vertical ducts 1320a-1320e. One or more airflows 1310a, 1310b, 1310c received from an entrance port (not shown) may be conducted through the channels and through the vertical ducts 1320a-1320e before exiting through an exit port (not shown). The airflows 1310a-1310c may be configured to remove heat from the surfaces of the PCBs 1304, 1308, from the transmitting coils 1302a, 1302b, 1302c, 1306a, 1306b and/or from the charging surface of the wireless charging device 1300.

In some implementations, the conformal coating or other overlay 1318 comprises a thermally conductive material and, together with one or more airflows 1310a, 1310b, 1310c, can facilitate the dissipation of heat generated in a device being charged or generated at the physical interface between the device being charged and the charging surface of the wireless charging device 1300. In some instances, the conformal coating or other overlay 1318 includes a porous material that allows the airflows 1310a-1310c to vent, at least partially, towards a device being charged. The porous material may include non-electrically conductive materials such as Polytetrafluoroethylene (PTFE) or the like.

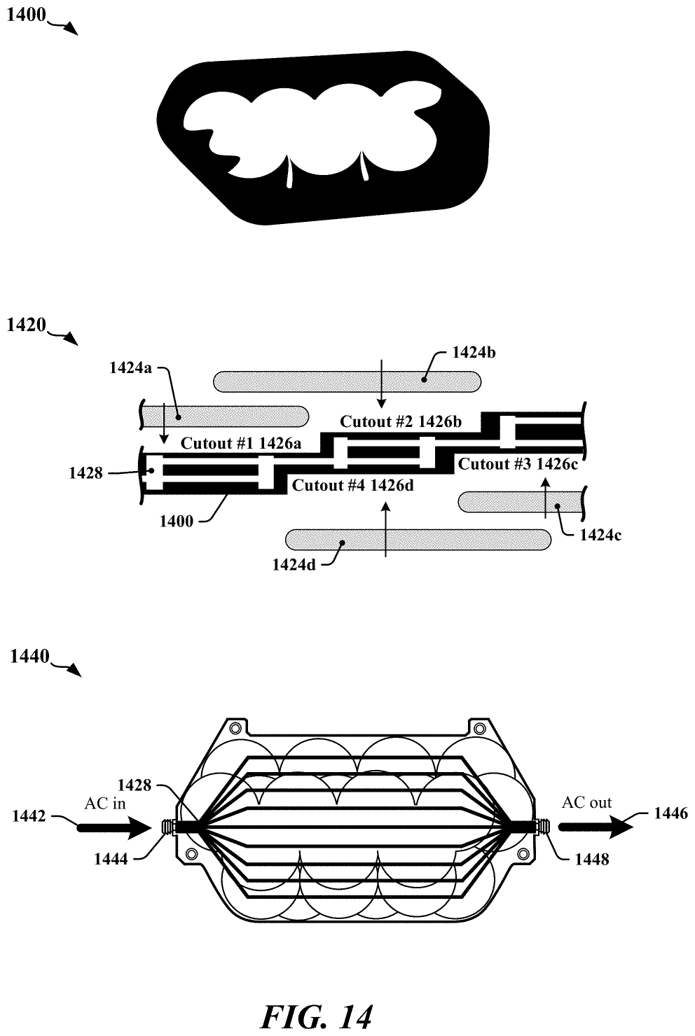

FIG. 14 illustrates certain aspects of a Litz coil substrate 1400 configured to facilitate removal of heat in accordance with certain aspects of this disclosure. The Litz coil substrate 1400 may be formed from a polymer, acetate, vinyl, nitrile rubber, latex, extruded polystyrene foam and/or another type of material. The Litz coil substrate 1400 may have multiple cutouts that enable the Litz coils 900 to be placed in position in an ordered assembly. In some examples, the cut-outs may be preformed when the Litz coil substrate 1400 is manufactured by 3D printing, molding, extrusion and/or low-pressure expansion. In some examples, the cut-outs may be formed by milling, grinding, etching, abrading, chemical erosion, chemical dissolution or by another technique suitable for use with the material used to form the Litz coil substrate 1400.

Certain aspects of the Litz coil substrate 1400 are illustrated in a cross-sectional view 1420. The illustrated Litz coil substrate 1400 provides a four-layer charging surface and the cross-sectional view 1420 illustrates an example of placement and assembly of four Litz coils 1424a-1424d in the wireless charging device, which is illustrated generally at 1440. The Litz coil substrate 1400 has a deep, first cutout 1426a in the Litz coil substrate 1400 that receives a first Litz coil 1424a. This first cutout 1426a may be formed as a complete circle in some examples. In other examples, the first cutout 1426a may overlap with another cutout in the same plane of the Litz coil substrate 1400.

When the first Litz coil 1424a has been secured within the first cutout 1426a, a second Litz coil 1424b may be placed in a second cutout 1426b in the Litz coil substrate 1400. When in position within the Litz coil substrate 1400, the second Litz coil 1424b lies in a parallel plane positioned above the plane that includes the first Litz coil 1424a. A portion of the second Litz coil 1424b overlaps a portion of the first Litz coil 1424a. The separation of the planes that include the horizontal center lines of the first Litz coil 1424a and the second Litz coil 1424b may be configured by the relative difference in depths of the first cutout 1426a and the second cutout 1426b.

The third Litz coil 1424c is received by a deep, third cutout 1426c in the Litz coil substrate 1400. This third cutout 1426c may be formed as a complete circle in some examples. In other examples, the third cutout 1426c may overlap with another cutout in the same plane. In one example, the third cutout 1426c may partially overlap the first cutout 1426a resulting in a through-hole, when the bottom surface of the first Litz coil 1424a is in the same plane as the top surface or some other portion of the third Litz coil 1424c.

When the third Litz coil 1424c has been secured within the third cutout 1426c, a fourth Litz coil 1424d may be placed in a fourth cutout 1426d. The fourth Litz coil 1424d lies in a plane below the plane that includes the third Litz coil 1424c. A portion of the fourth Litz coil 1424d overlaps a portion of the third Litz coil 1424c when secured within the Litz coil substrate 1400. The separation of the planes that include the horizontal center lines of the third Litz coil 1424c and the fourth Litz coil 1424d may be configured by the relative difference in depths of the third cutout 1426c and the fourth cutout 1426d.

The Litz coil 1424a-1424d may be secured within the Litz coil substrate 1400 through a pressure fit, including when the Litz coil substrate 1400 is manufactured from a foam material. In some examples, the Litz coil 1424a-1424d may be secured within the Litz coil substrate 1400 by adhesive. In some examples, the Litz coil 1424a-1424d may be secured within the Litz coil substrate 1400 by mechanical means.

A system of interconnecting channels or ducts 1428 can be seen in the cross-sectional view 1420. In one example, horizontal ducts (referred to herein as channels) interconnect with vertical ducts. The system of interconnecting channels or ducts 1428 may be configured to direct or conduct a received airflow 1442 around or through the Litz coils 1424a-1424d and toward the charging surface of the wireless charging device. With reference to the two-dimensional transparent view 1440, the airflow 1442 may be received through an entrance port 1444 and may be conducted through the system of interconnecting channels or ducts 1428 before exiting as an exhaust flow 1446 through an exit port 1448. In one example, the entrance port 1444 and/or the exit port 1448 comprise a threaded pipe configured to couple the airflow 1442 and the exhaust flow 1446 to an external cooling or ventilation system as found, for example, in an automobile, bus, train, airplane, seagoing vessel or other vehicle. In other examples, the entrance port 1444 and/or the exit port 1448 is part of a snap-fit coupling or a coupling that is secured using an elastic material such as a rubber, latex or synthetic rubber material. The air flowing through the interconnecting channels or ducts 1428 can remove heat from the surfaces of the Litz coils 1424a-1424d, the Litz coil substrate 1400 and from one or more surfaces of the wireless charging device.

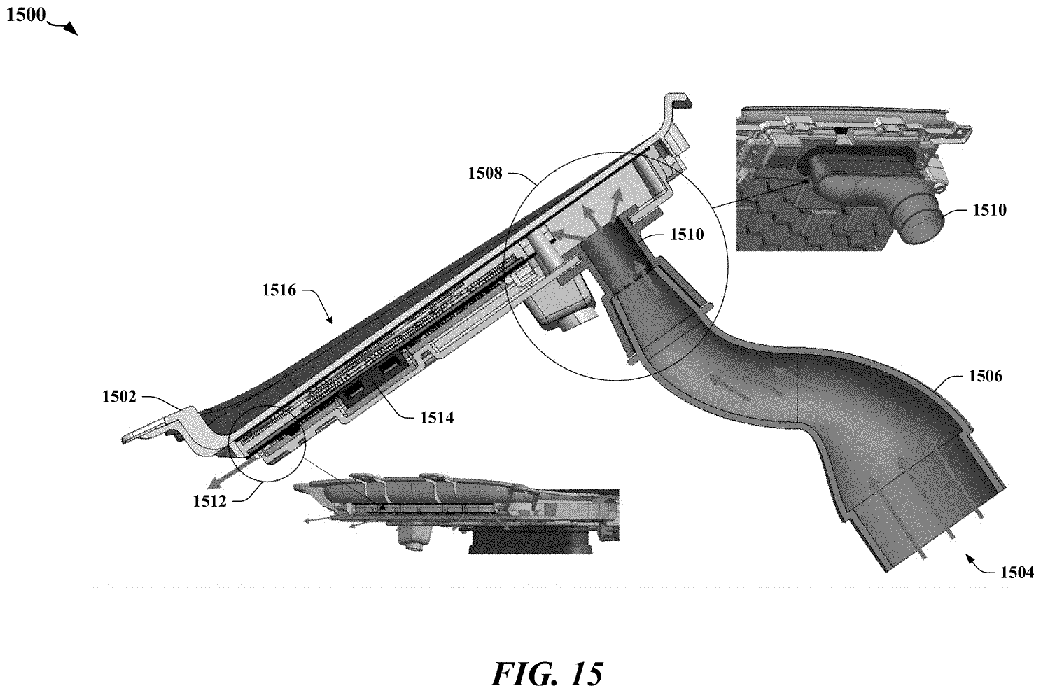

FIG. 15 shows a system 1500 in which a coupling mechanism 1508 is used to provide a wireless charging device 1502 with an airflow 1504 received from an air-conditioning system or the like. The system 1500 may be deployed in an automobile, bus, train, airplane, seagoing vessel or other vehicle that provides air conditioning, forced-air ventilation or another source of airflow. The wireless charging device 1502 may include interconnecting channels or ducts of the type illustrated in FIGS. 13 and 14, for example. Alternatively, or additionally, the wireless charging device 1502 may include an open area, channel or duct that provides the airflow on or around a processing circuit 1514 or a current driving circuit in the wireless charging device 1502. In the illustrated example, the exhaust airflow is vented through a port 1512 to the exterior of the wireless charging device 1502. In other examples, the exhaust airflow may be recovered by an air conditioning system.

The coupling mechanism 1508 may be configured to mechanically secure the wireless charging device 1502 to the source of airflow. In the illustrated example, the coupling system provides a snap-fit coupling, a screw-fit coupling or a coupling that is secured using an elastic material such as a rubber, latex or synthetic rubber material. In one example, the coupling mechanism 1508 includes a rubber receptacle 1510 fixed to the wireless charging device 1502 and configured to engage a metal, ceramic or polymer nozzle or funnel 1506 through which the airflow is delivered. The exhaust airflow may be vented through the port 1512 to the exterior of the wireless charging device 1502, through a porous material on the surface 1516 of the wireless charging device 1502, through a return connection to the source of the airflow, or through other mechanisms or conduits.

In some instances, the coupling mechanism 1508 may have sufficient mechanical strength to operate as a mount for the wireless charging device 1502.

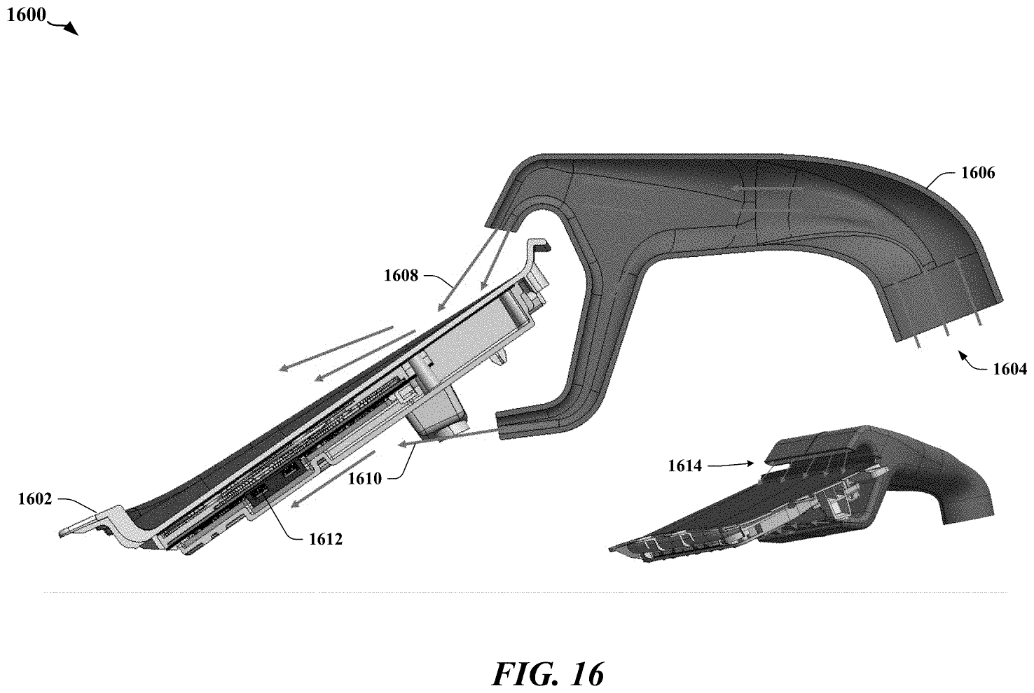

FIG. 16 shows a system 1600 in which a wireless charging device 1602 receives a flow of air 1604 from an air-conditioning system, ventilation system or other source of forced air. In certain examples, the system 1600 may be deployed in an automobile, bus, train, airplane, seagoing vessel or other vehicle that provides air conditioning or forced air ventilation. The wireless charging device 1602 may include interconnecting channels or ducts as illustrated in FIGS. 13 and 14, for example. Alternatively, or additionally, the wireless charging device 1602 may include an open area, channel or duct configured to direct airflow onto or around a processing circuit 1612 or current driving circuit in the wireless charging device 1602.

In the illustrated example, multiple airflows 1608, 1610 are directed toward the exterior of the wireless charging device 1602. One or more of the airflows 1608, 1610 may be directed toward an open input port of the wireless charging device 1602 such that the wireless charging device 1602 receives an inflow of cooling air into an open area, channel or duct. In the illustrated example, the airflows 1608, 1610 are provided by some combination of nozzles or vents in a manifold 1606 that is configured to distribute a flow of air 1604 received from the air-conditioning system, ventilation system or other source of forced air. Elongated nozzles or vents 1614 provided along a side of the wireless charging device 1602 may direct a broad flow of air across the surface of the wireless charging device 1602.

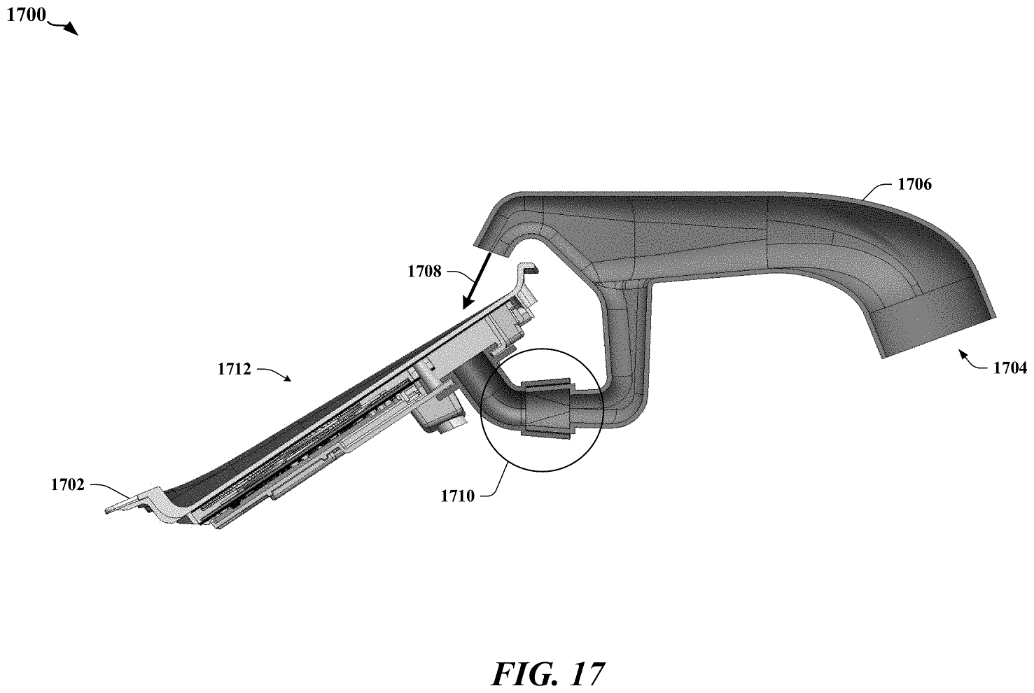

FIG. 17 shows a combination system 1700 in which a wireless charging device 1702 is coupled to the inflow of air 1704 received from an air-conditioning system, ventilation system or other source of forced air. A first vent, duct or nozzle is configured or arranged to direct a portion of the inflow of air 1704 as an external airflow 1708 that is directed onto an exterior surface of the wireless charging device 1702. A second duct or nozzle is configured to introduce a portion of the inflow of air 1704 directly into the interior of the wireless charging device 1702. The combination system 1700 may be deployed in an automobile or other type of vehicle that provides air conditioning or a source of airflow. The wireless charging device 1702 may include interconnecting channels or ducts as illustrated in FIGS. 13 and 14, for example. Alternatively, or additionally, the wireless charging device 1702 may include an open area, channel or duct that provides the airflow on or around a processing circuit or a current driving circuit in the wireless charging device 1702.

A coupling system 1710 may secure the wireless charging device 1702 to a manifold 1706 that distributes the inflow of air 1704. The coupling system 1710 may comprise a snap-fit coupling, a screw-fit coupling or a coupling that is secured through an elastic material such as a rubber, latex or synthetic rubber material. In one example, the coupling system 1710 includes a rubber receptacle fixed to the wireless charging device 1702 and configured to engage a metal, ceramic or polymer nozzle or funnel through which the airflow is delivered. The airflow may be vented by the wireless charging device 1702 through an exit port, through a porous material on the surface 1712 of the wireless charging device 1702, through a return connection to the source of the airflow, or by other means. In other examples, the airflow may be recovered by an air conditioning system.

One or more airflows 1708 may be directed toward the exterior of the wireless charging device 1702. In one example, the external airflow 1708 is directed toward an input port of the wireless charging device 1702 such that the wireless charging device 1702 receives an inflow of cooling air into an open area, channel or duct. In another example, the external airflow 1708 is directed toward a charging surface 1712 of the wireless charging device 1702 such that the surface of the wireless charging device 1702 and any device being charged receive an inflow of cooling air. The external airflow 1708 may be received from some combination of nozzles or vents supplied by the manifold 1706. Elongated nozzles or vents provided along a side of the wireless charging device 1702 may direct a broad flow of air across the surface of the wireless charging device 1702. In some instances, the manifold 1706 may have sufficient mechanical strength to operate as a mount for the wireless charging device 1702.

According to certain aspects of this disclosure, a wireless charging device may be equipped with a cooling fan, impeller or blower. In some examples, the wireless charging device may be deployed or installed in a vehicle that provides a tight or relatively small volume space for installing the wireless charging device. The cooling fan, impeller or blower may be activated without significantly increasing ambient noise within a passenger cabin of the vehicle.

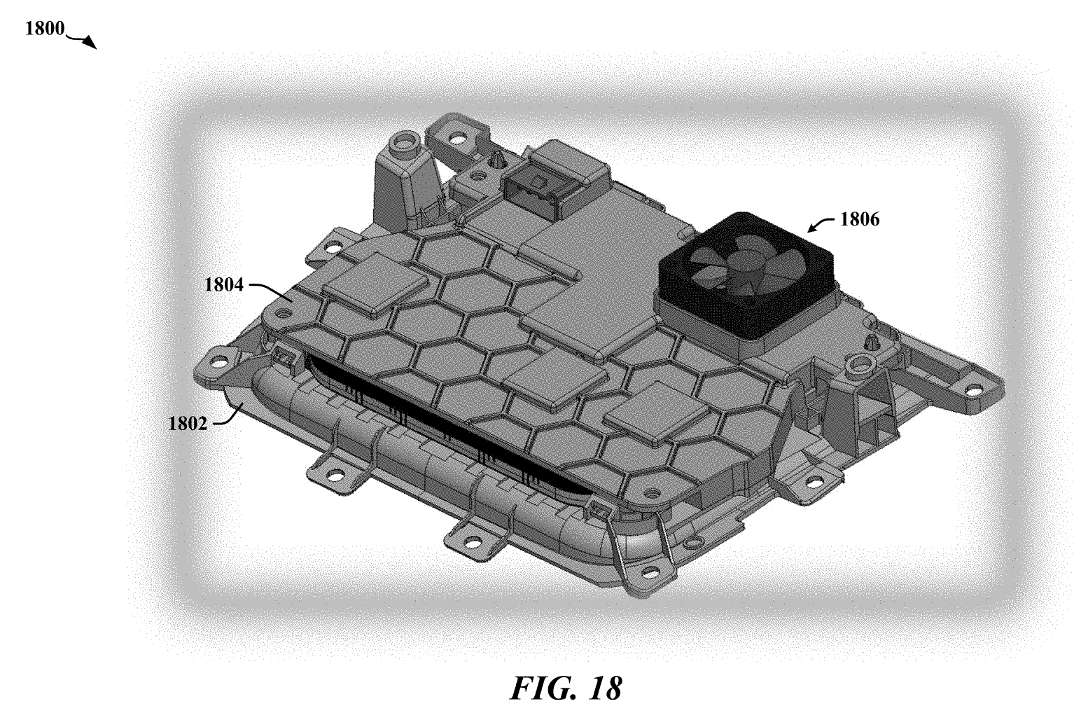

FIG. 18 provides a view of a first side of a wireless charging device 1800 that can be cooled by a forced air flow produced by an external fan 1806. The wireless charging device 1800 may be configured to operate as a multi-coil free-positioning wireless charging system. The external fan 1806 is located on an outer surface of the wireless charging device 1800.

In the illustrated example, the wireless charging device 1800 has a housing that includes a front portion 1802 and back or rear portion 1804. The external fan 1806 may comprise an axial fan configured to drive an airflow into the wireless charging device 1800 or pull an exhaust airflow from the interior of the wireless charging device 1800. The external fan 1806 may be directly mounted to the rear portion 1804. In some examples, the rear portion 1804 is constructed, at least in part, from a metal such as aluminum or copper that can assist heat dissipation. In the illustrated example, the external fan 1806 is mounted on the outside of an aluminum rear portion 1804 of the housing. A configuration having an externally-mounted fan can support fan types that have a profile or height that are not suited for inclusion within the housing. In some examples, an externally-mounted fan has a 50 mm×50 mm cross-sectional area and a height that can vary from 10 mm to 32 mm. The physical dimensions of the illustrated external fan 1806 may be determined by the volume of air to be moved by the external fan 1806. In some examples the volume of air moved by the external fan 1806 is measured or characterized as cubic feet per minute (CFM). In one example, a 50 mm×50 mm axial fan can produce airflow at up to 31.6 CFM. In the latter example, an axial fan can be operated at variable power to produce between 6.3 CFM and 31.6 CFM.

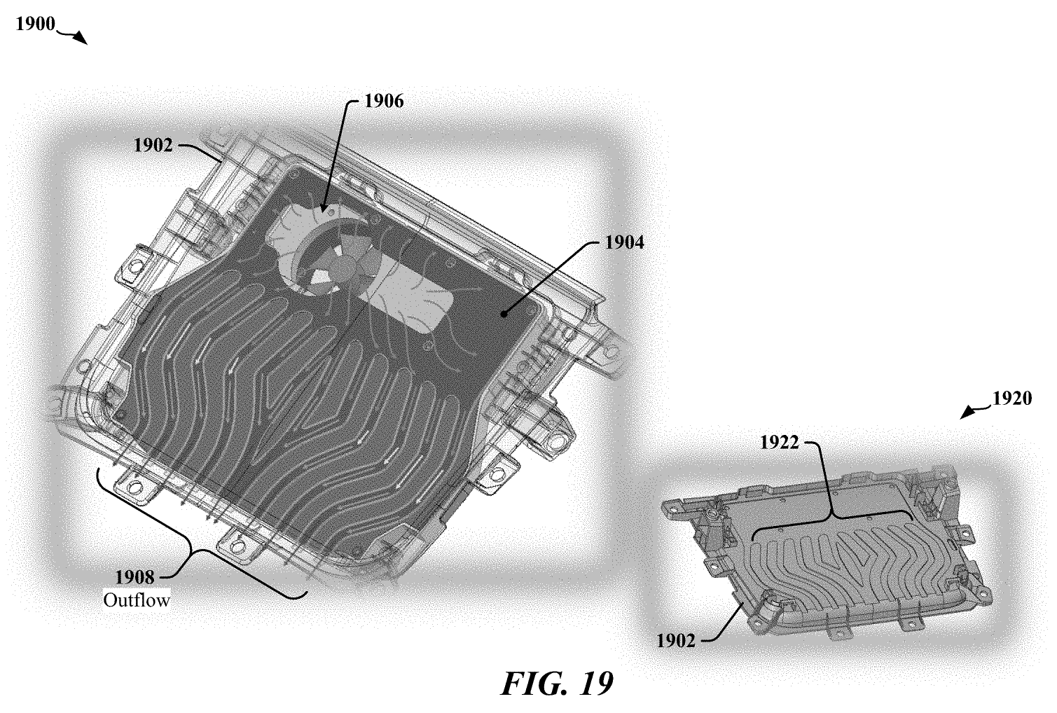

FIG. 19 provides a view of a second side of a wireless charging device 1900 that can be cooled by a forced air flow produced by an external fan 1906. The wireless charging device 1900 may correspond to the wireless charging device 1800 of FIG. 18 and may be configured to operate as a multi-coil free-positioning wireless charging system. The external fan 1906 is located on an outer surface of the wireless charging device 1900.

In the illustrated example, the wireless charging device 1900 has a housing that includes a front portion 1902 and back or rear portion 1904. Here the rear portion 1904 is adapted or configured to assist air flow. In the drawing, the front portion 1902 is illustrated as a transparent component, exposing certain internal features of the rear portion 1904.

The external fan 1906 may comprise an axial fan configured to drive an airflow into the wireless charging device 1900 or to pull an exhaust airflow from the interior of the wireless charging device 1900. The external fan 1906 may be directly mounted to the rear portion 1904. In some examples, the rear portion 1904 includes or is constructed from a metal such as aluminum or copper that can assist heat dissipation. In the illustrated example, the fan 1906 is mounted within the housing.

The internal surface of the rear portion 1904 may be configured with channels 1910 or grooves that conduct air flowing from the fan 1906 across an area corresponding to the transmitting coils, current generation circuits and controllers of the wireless charging device 1900. In some examples, the channels 1910 provide a pathway to a slotted, elongated opening on the rear portion 1904 that operates to vent an outflow 1908 of air received from the channels 1910. The width, height and routing of the channels 1910 can be configured according to airflow needs or requirements.

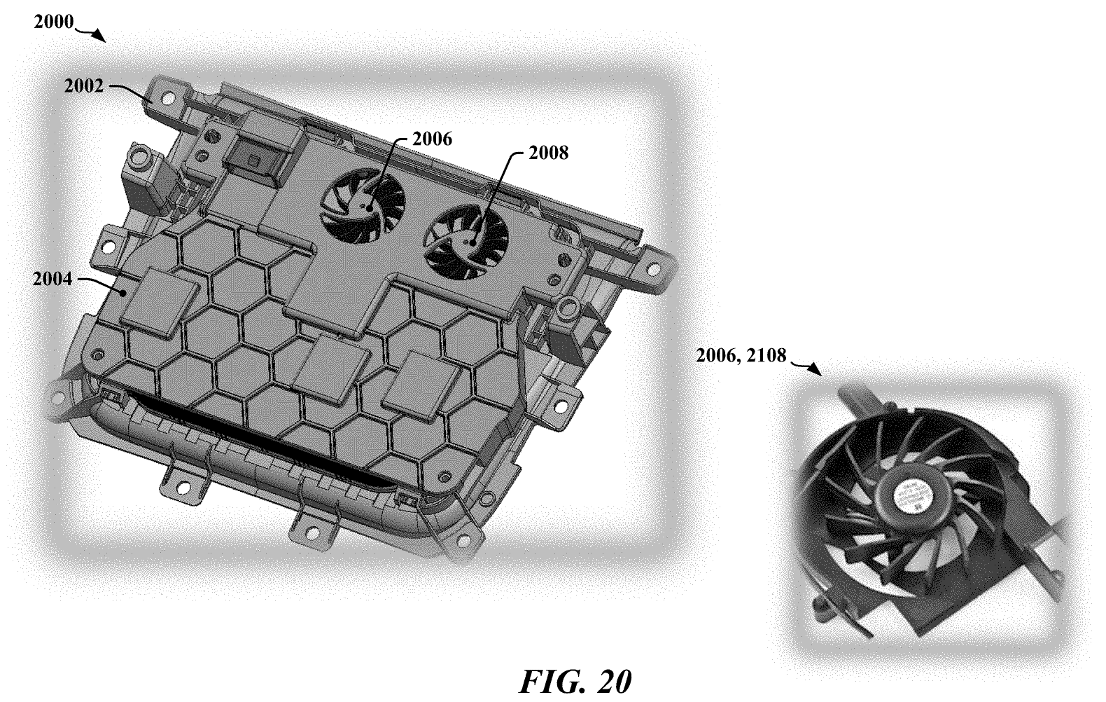

FIG. 20 provides a view of a first side of a wireless charging device 2000 that can be cooled by a forced air flow produced by one or more internal impeller fans 2006, 2008. The wireless charging device 2000 may be configured to operate as a multi-coil free-positioning wireless charging system. The internal impeller fans 2006, 2008 may be located largely within the housing of wireless charging device 2000.

In the illustrated example, the wireless charging device 2000 has a housing that includes a front portion 2002 and back or rear portion 2004, and active cooling is achieved using two internal impeller fans 2006, 2008 that can be mounted adjacent to the inner surface of the rear portion 2004. In some examples, the rear portion 2004 includes or is constructed from a metal such as aluminum or copper that can assist heat dissipation. In the illustrated example, the mounting of the internal impeller fans 2006, 2008 on the inside of housing can limit the types and sizes of fan that can be used. In some examples, more than two internal impeller fans 2006, 2008 may be provided in the wireless charging device 2000. In some instances, the number of active internal impeller fans 2006, 2008 may be dynamically configured to produce a desired or required maximum airflow. In some instances, the speed of operation of the internal impeller fans 2006, 2008 may be dynamically configured to produce a desired or required maximum airflow.

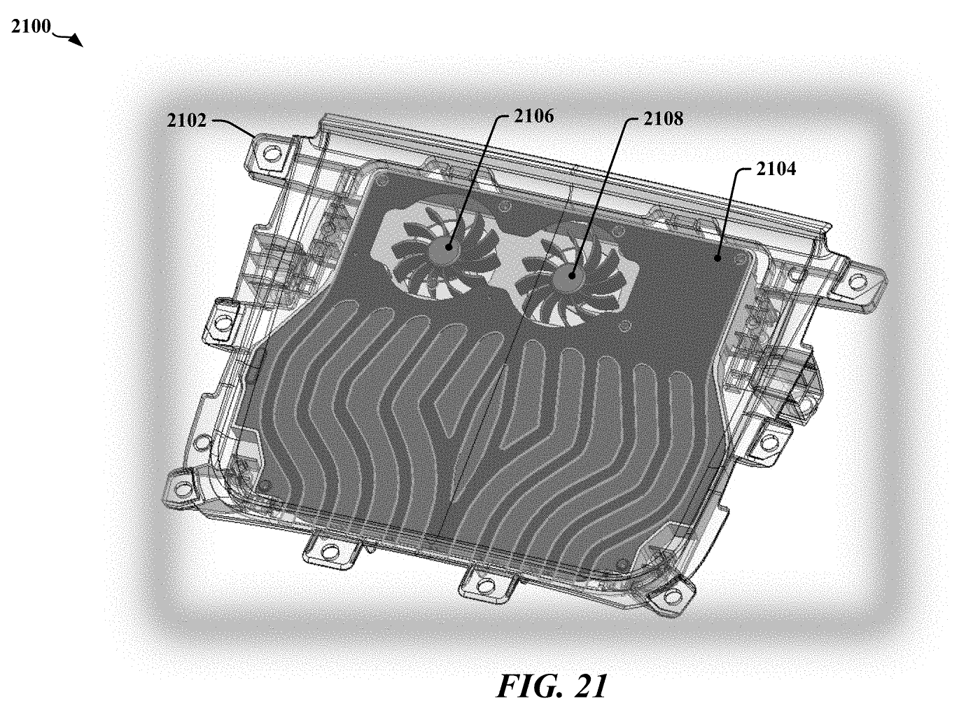

FIG. 21 provides a view of a second side of a wireless charging device 2100 that can be cooled by a forced air flow produced by one or more internal impeller fans 2106, 2108. The wireless charging device 2100 may correspond to the wireless charging device 2000 of FIG. 20 and may be configured to operate as a multi-coil free-positioning wireless charging system. The internal impeller fans 2106, 2108 may be located largely within the housing of wireless charging device 2100.

In the illustrated example, the wireless charging device 2100 has a housing that includes a front portion 2102 and back or rear portion 2104. The front portion 2102 and/or the back or rear portion 2104 may be adapted or configured to assist air flow. In the drawing, the front portion 2102 is illustrated as a transparent component, thereby exposing certain internal features of the rear portion 2104.

The internal impeller fans 2106, 2108 may be directly mounted to the rear portion 2104.

In some examples, the rear portion 2104 includes or is constructed from a metal such as aluminum or copper that can assist heat dissipation. The internal surface of the rear portion 2104 may be configured with channels or grooves that conduct air flowing from the internal impeller fans 2106, 2108 across an area corresponding to the transmitting coils, current generation circuits and controllers of the wireless charging device 2100. In some examples, the channels provide a pathway to a slotted, elongated opening on the rear portion 2104 that operates to vent an outflow of air received from the air channels. The width, height and routing of the air channels can be configured according to airflow needs or requirements.

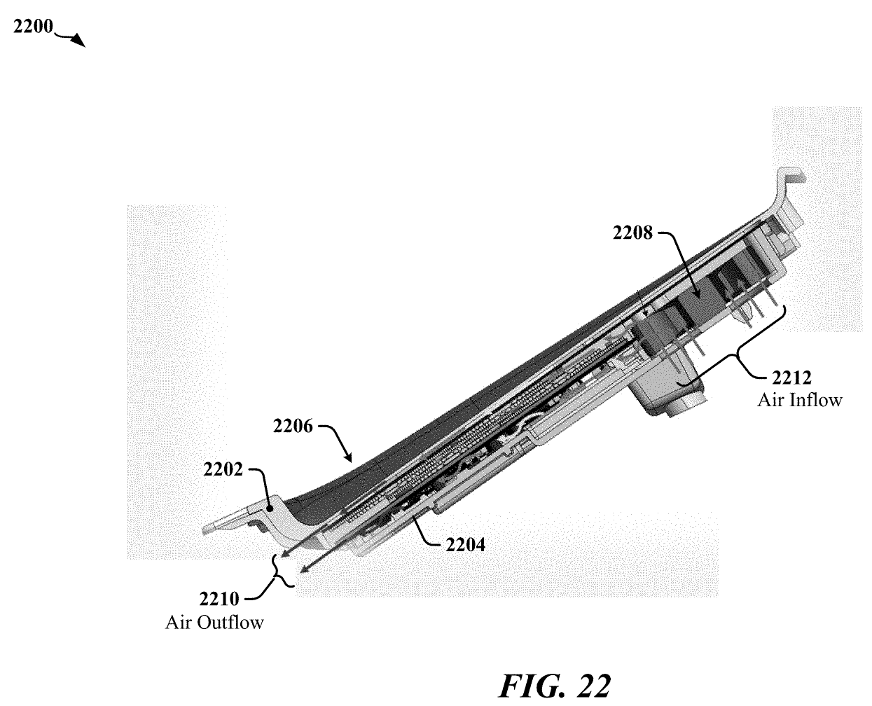

FIG. 22 provides a side view of a multi-coil free-positioning wireless charging device 2200 that can be cooled by a forced airflow produced by a fan assembly 2208 that is located largely within the housing of wireless charging device 2200. The fan assembly 2208 may comprise one or more internal impeller fans. In the illustrated example, the wireless charging device 2200 has a housing that includes a front portion 2202 and back or rear portion 2204. The front portion 2202 and/or the back or rear portion 2204 may be adapted or configured to assist air flow. The wireless charging device 2200 may correspond to a wireless charging device 2000 or 2100 illustrated in any of FIGS. 18-21.

An air intake and/or the fan assembly 2208 may be configured to receive an inflow 2212 of air. In the illustrated example, impellers in the fan assembly 2208 force air directly over internal components including transmitting coils, current generation circuits and controllers of the wireless charging device 2300 or 2100 through air channels configured in accordance with certain aspects of this disclosure.

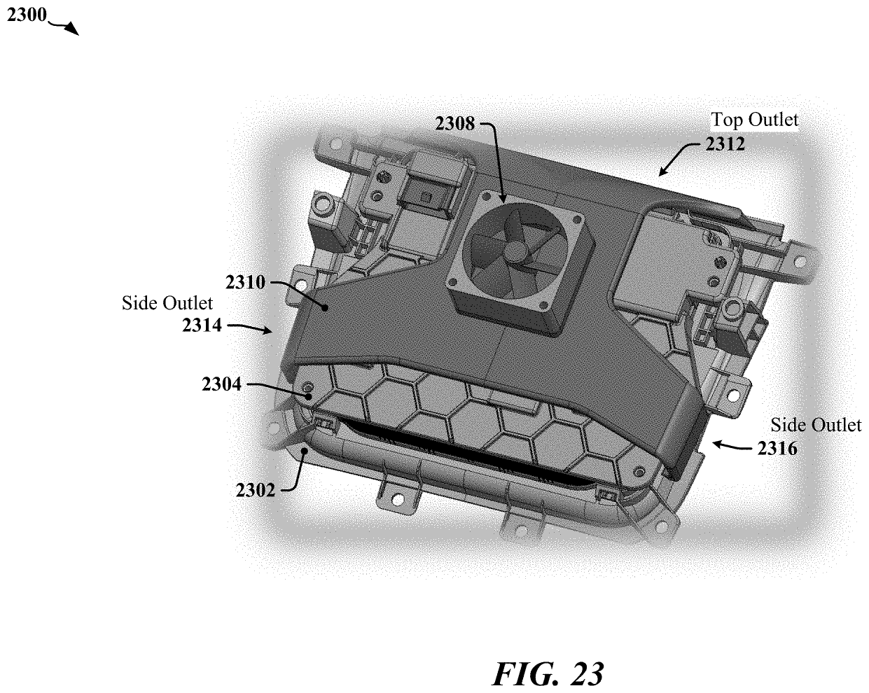

FIG. 23 illustrates an example of a multi-coil free-positioning wireless charging device 2300 that can be cooled by a forced airflow attachment. Here the airflow is produced by a separate, attachable cooling device 2310 that can be attached to the wireless charging device 2300 and that operates as a funnel. In the illustrated example, the wireless charging device 2300 has a housing that includes a front portion 2302 and back or rear portion 2304, and the attachable cooling device 2310 may be configured to mounted on the housing of the wireless charging device 2300 using snap fit structures or fasteners.

The airflow may be produced by one or more fans 2308 that drive air through the funnel to outlets 2312, 2314, 2316 that are configured to direct air toward a charging surface of the wireless charging device 2300 and/or any receiving devices being charged by the wireless charging device 2300. The cooling device 2310 may provide bottom or top outlets 2312 and side outlets 2314, 2316. In some examples, the cooling device 2310 may include or may be constructed from a polymer or a metal such as aluminum or copper that can assist heat dissipation.

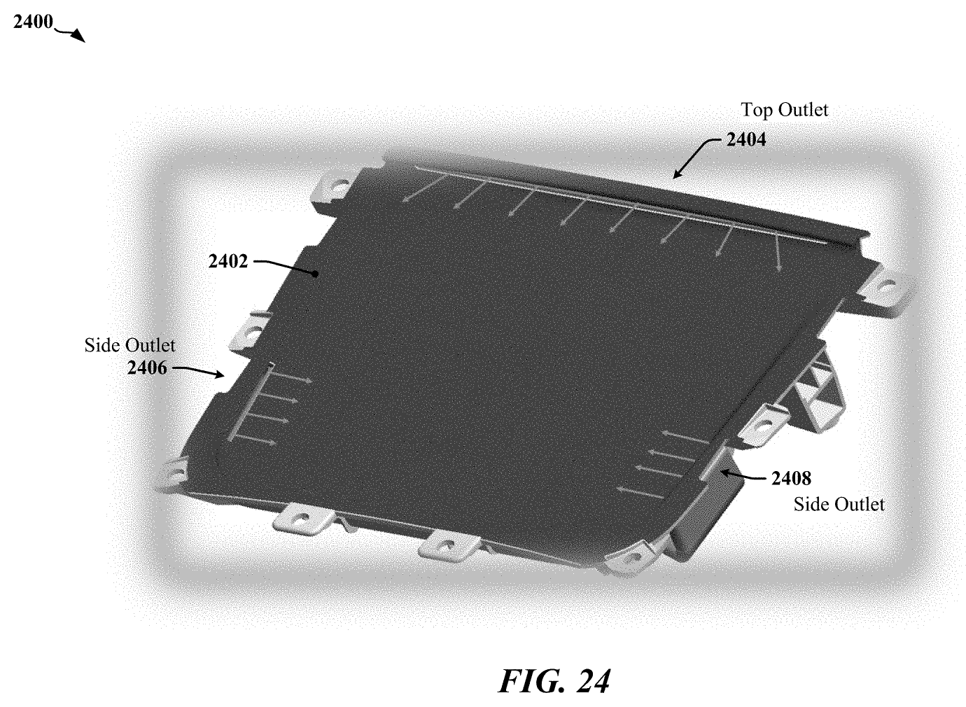

FIG. 24 provides a reverse view of an attachable cooling device 2400 that may correspond in some respects to the wireless charging device 2300 illustrated in FIG. 23. Outlets 2404, 2406, 2408 in the attachable cooling device 2400 may direct air on to or across a gap provided at a surface 2402 configured to interface with a charging surface of an attached wireless charging device.

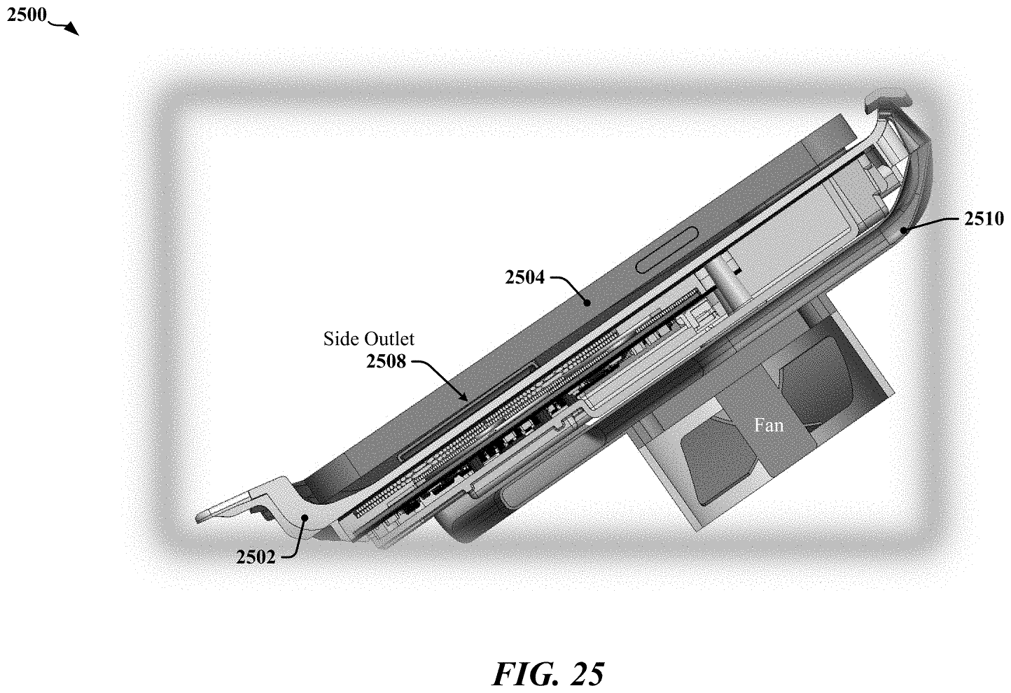

FIG. 25 provides a side view of a wireless charging device 2500 that may correspond in some respects to the wireless charging device 2300 illustrated in FIG. 23. A side outlet 2508 in the cooling device 2510 may direct air on to or across a charging surface 2502 of the wireless charging device 2500 and onto a receiving device 2504 being charged by the wireless charging device 2500.

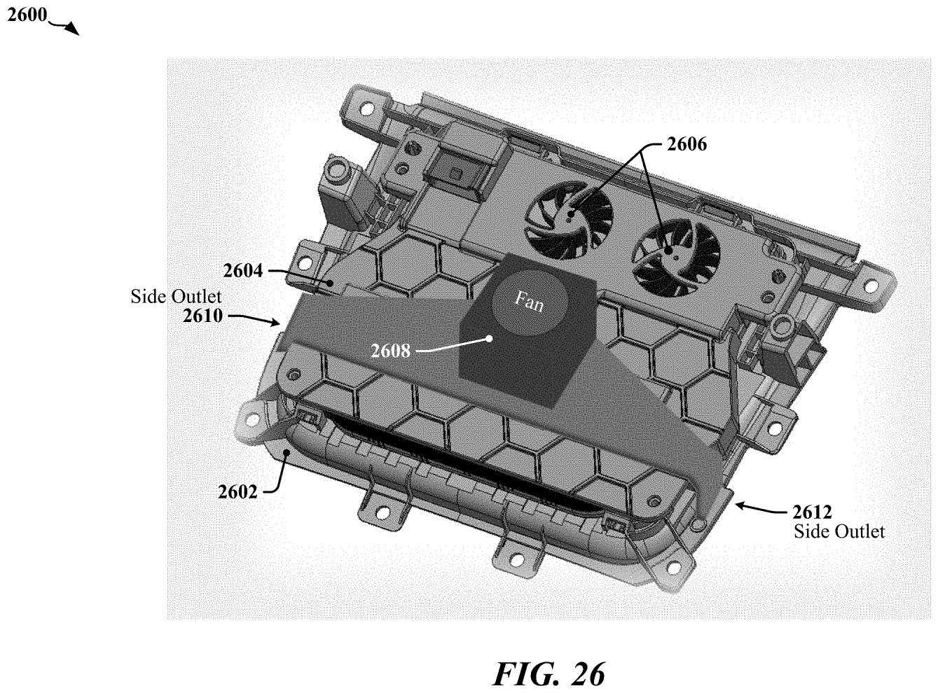

FIG. 26 illustrates an example in which a multi-coil free-positioning wireless charging device 2600 can be cooled by a hybrid forced airflow. Here, airflows are provided by one or more impeller fans 2606 located largely within the housing of wireless charging device 2600 and by a separate, attachable cooling device 2608 that operates as a funnel.

In the illustrated example, the wireless charging device 2600 has a housing that includes a front portion 2602 and back or rear portion 2604, and active cooling is achieved using a pair of impeller fans 2606 that can be mounted adjacent to the inner surface of the rear portion 2604. In some examples, the rear portion 2604 includes or is constructed from a metal such as aluminum or copper that can assist heat dissipation.

The cooling device 2608 may operate as a funnel and may be fitted to the housing of the wireless charging device 2600 using snap fit structures or fasteners. The cooling device 2608 can produce an airflow using one or more fans that drive air through the funnel to outlets 2610, 2612 that are configured to direct air toward a charging surface of the wireless charging device 2600 and/or any receiving devices being charged by the wireless charging device 2600. In some examples, the cooling device 2608 may include or may be constructed from a polymer or a metal such as aluminum or copper that can assist heat dissipation.

### Example of a Processing Circuit

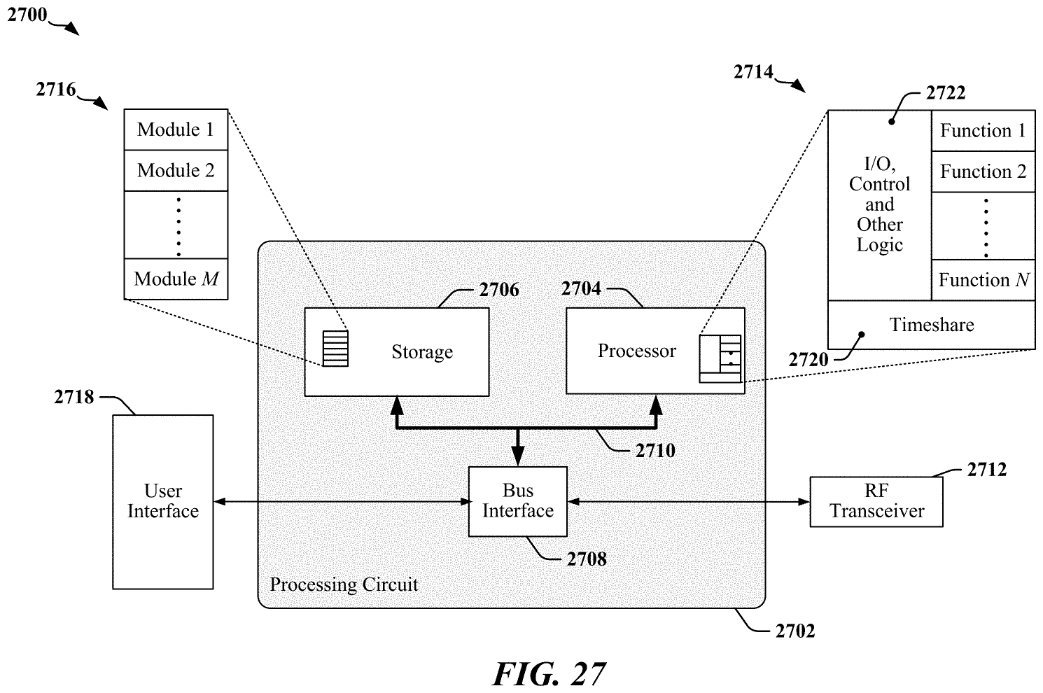

FIG. 27 illustrates an example of a hardware implementation for an apparatus 2700 that may be incorporated in a charging device or in a receiving device that enables a battery to be wirelessly charged. In some examples, the apparatus 2700 may perform one or more functions disclosed herein. In accordance with various aspects of the disclosure, an element, or any portion of an element, or any combination of elements as disclosed herein may be implemented using a processing circuit 2702. The processing circuit 2702 may include one or more processors 2704 that are controlled by some combination of hardware and software modules. Examples of processors 2704 include microprocessors, microcontrollers, digital signal processors (DSPs), SoCs, ASICs, field programmable gate arrays (FPGAs), programmable logic devices (PLDs), state machines, sequencers, gated logic, discrete hardware circuits, and other suitable hardware configured to perform the various functionality described throughout this disclosure. The one or more processors 2704 may include specialized processors that perform specific functions, and that may be configured, augmented or controlled by one of the software modules 2716. The one or more processors 2704 may be configured through a combination of software modules 2716 loaded during initialization, and further configured by loading or unloading one or more software modules 2716 during operation.

In the illustrated example, the processing circuit 2702 may be implemented with a bus architecture, represented generally by the bus 2710. The bus 2710 may include any number of interconnecting buses and bridges depending on the specific application of the processing circuit 2702 and the overall design constraints. The bus 2710 links together various circuits including the one or more processors 2704, and storage 2706. Storage 2706 may include memory devices and mass storage devices, and may be referred to herein as computer-readable media and/or processor-readable media. The storage 2706 may include transitory storage media and/or non-transitory storage media.

The bus 2710 may also link various other circuits such as timing sources, timers, peripherals, voltage regulators, and power management circuits. A bus interface 2708 may provide an interface between the bus 2710 and one or more transceivers 2712. In one example, a transceiver 2712 may be provided to enable the apparatus 2700 to communicate with a charging or receiving device in accordance with a standards-defined protocol. Depending upon the nature of the apparatus 2700, a user interface 2718 (e.g., keypad, display, speaker, microphone, joystick) may also be provided, and may be communicatively coupled to the bus 2710 directly or through the bus interface 2708.

A processor 2704 may be responsible for managing the bus 2710 and for general processing that may include the execution of software stored in a computer-readable medium that may include the storage 2706. In this respect, the processing circuit 2702, including the processor 2704, may be used to implement any of the methods, functions and techniques disclosed herein. The storage 2706 may be used for storing data that is manipulated by the processor 2704 when executing software, and the software may be configured to implement any one of the methods disclosed herein.

One or more processors 2704 in the processing circuit 2702 may execute software. Software shall be construed broadly to mean instructions, instruction sets, code, code segments, program code, programs, subprograms, software modules, applications, software applications, software packages, routines, subroutines, objects, executables, threads of execution, procedures, functions, algorithms, etc., whether referred to as software, firmware, middleware, microcode, hardware description language, or otherwise. The software may reside in computer-readable form in the storage 2706 or in an external computer-readable medium. The external computer-readable medium and/or storage 2706 may include a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a “flash drive,” a card, a stick, or a key drive), RAM, ROM, a programmable read-only memory (PROM), an erasable PROM (EPROM) including EEPROM, a register, a removable disk, and any other suitable medium for storing software and/or instructions that may be accessed and read by a computer. The computer-readable medium and/or storage 2706 may also include, by way of example, a carrier wave, a transmission line, and any other suitable medium for transmitting software and/or instructions that may be accessed and read by a computer. Computer-readable medium and/or the storage 2706 may reside in the processing circuit 2702, in the processor 2704, external to the processing circuit 2702, or be distributed across multiple entities including the processing circuit 2702. The computer-readable medium and/or storage 2706 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

The storage 2706 may maintain and/or organize software in loadable code segments, modules, applications, programs, etc., which may be referred to herein as software modules 2716. Each of the software modules 2716 may include instructions and data that, when installed or loaded on the processing circuit 2702 and executed by the one or more processors 2704, contribute to a run-time image 2714 that controls the operation of the one or more processors 2704. When executed, certain instructions may cause the processing circuit 2702 to perform functions in accordance with certain methods, algorithms and processes described herein.

Some of the software modules 2716 may be loaded during initialization of the processing circuit 2702, and these software modules 2716 may configure the processing circuit 2702 to enable performance of the various functions disclosed herein. For example, some software modules 2716 may configure internal devices and/or logic circuits 2722 of the processor 2704, and may manage access to external devices such as a transceiver 2712, the bus interface 2708, the user interface 2718, timers, mathematical coprocessors, and so on. The software modules 2716 may include a control program and/or an operating system that interacts with interrupt handlers and device drivers, and that controls access to various resources provided by the processing circuit 2702. The resources may include memory, processing time, access to a transceiver 2712, the user interface 2718, and so on.

One or more processors 2704 of the processing circuit 2702 may be multifunctional, whereby some of the software modules 2716 are loaded and configured to perform different functions or different instances of the same function. The one or more processors 2704 may additionally be adapted to manage background tasks initiated in response to inputs from the user interface 2718, the transceiver 2712, and device drivers, for example. To support the performance of multiple functions, the one or more processors 2704 may be configured to provide a multitasking environment, whereby each of a plurality of functions is implemented as a set of tasks serviced by the one or more processors 2704 as needed or desired. In one example, the multitasking environment may be implemented using a timesharing program 2720 that passes control of a processor 2704 between different tasks, whereby each task returns control of the one or more processors 2704 to the timesharing program 2720 upon completion of any outstanding operations and/or in response to an input such as an interrupt. When a task has control of the one or more processors 2704, the processing circuit is effectively specialized for the purposes addressed by the function associated with the controlling task. The timesharing program 2720 may include an operating system, a main loop that transfers control on a round-robin basis, a function that allocates control of the one or more processors 2704 in accordance with a prioritization of the functions, and/or an interrupt driven main loop that responds to external events by providing control of the one or more processors 2704 to a handling function.

In one implementation, the apparatus 2700 includes or operates as a wireless charging device that has a battery charging power source coupled to a charging circuit, a plurality of charging cells and a controller, which may be included in one or more processors 2704. The plurality of charging cells may be configured to provide a charging surface. At least one coil may be configured to direct an electromagnetic field through a charge transfer area of each charging cell.

In one example, a wireless charging device has a plurality of planar power transmitting coils, a driver circuit and at least one substrate having one or more channels formed therein. The one or more channels may be configured to receive a flow of air at a port of entry and to conduct the flow of air through the substrate to a port of exit. The plurality of planar power transmitting coils may be supported by at least one substrate. Each planar power transmitting coil may be formed as a spiral winding surrounding a power transfer area. The driver circuit may be configured to provide a charging current to one or more of the plurality of planar power transmitting coils when a chargeable device is placed on or near the wireless charging device. The one or more channels may be configured to conduct the flow of air past or through the plurality of planar power transmitting coils and the driver circuit.

In one example, each planar power transmitting coil is formed by spiral winding a multi-strand wire, each strand in the multi-strand wire being electrically insulated from each other strand in the multi-strand wire.

In one example, the wireless charging device has a PCB that has one or more holes provided therein. The one or more holes may be configured to conduct at least a portion of the airflow between channels in two substrates.

In some examples, the wireless charging device has a coil substrate with a plurality of cut-outs formed therein. The plurality of cut-outs may be configured to secure the plurality of planar power transmitting coils in a preconfigured three-dimensional arrangement. The preconfigured three-dimensional arrangement provides a charging surface through a top surface of the coil substrate as a combination of power transfer areas of the plurality of planar power transmitting coils. A portion of the airflow may be directed toward the charging surface. The charging surface may include a porous material that passes some of the airflow that is directed toward the charging surface to the exterior of the wireless charging device. The preconfigured three-dimensional arrangement may provide planar power transmitting coils in a plurality of vertical planes.

In one example, the coil substrate is formed from a molded polymer and has one or more horizontal channels that interconnect with a plurality of vertical ducts. The one or more horizontal channels and the plurality of vertical ducts may be formed in the coil substrate during molding.

In one example, the coil substrate is formed by three-dimensional printing and includes interconnected horizontal channels and vertical ducts that are formed in the coil substrate during printing.

In one example, the coil substrate is formed from a polymer, acetate, vinyl, nitrile rubber, latex, extruded polystyrene foam and includes interconnected horizontal channels and vertical ducts that are formed in the coil substrate during printing formed milling, grinding, etching, abrading, chemical erosion or chemical dissolution.

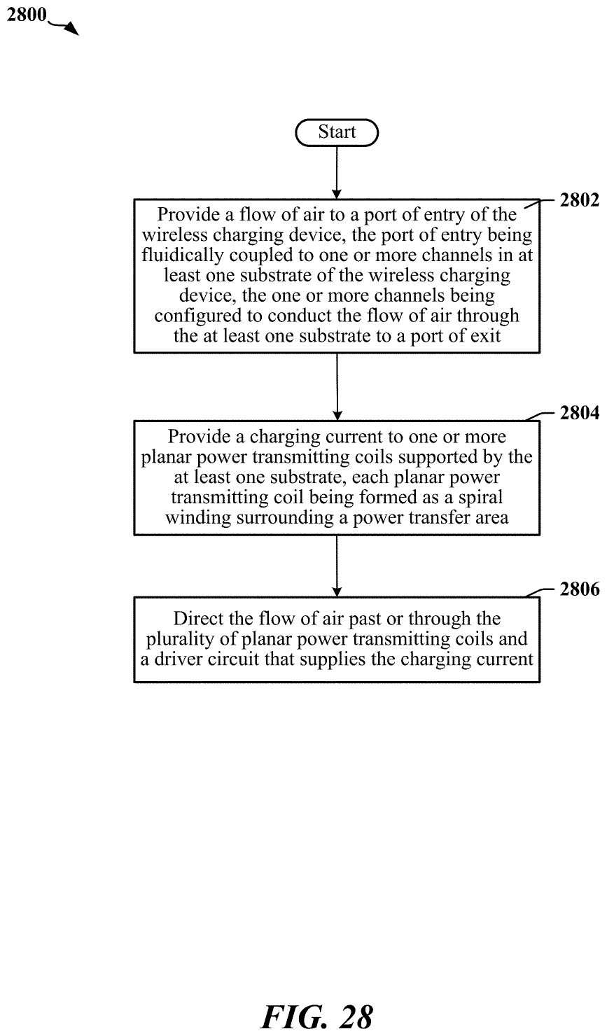

FIG. 28 is a flowchart 2800 illustrating a method for operating a wireless charging device. At block 2802, a flow of air is provided to a port of entry of the wireless charging device. The port of entry may be fluidically coupled to one or more channels in at least one substrate of the wireless charging device. The one or more channels may be configured to conduct the flow of air through the at least one substrate to a port of exit. In one example, the flow of air is received from an air conditioning system. In another example, the flow of air is received from a fan or blower.

At block 2804, a charging current is provided to one or more planar power transmitting coils supported by the at least one substrate. Each planar power transmitting coil may be formed as a spiral winding surrounding a power transfer area. At block 2806, the flow of air may be directed past or through the plurality of planar power transmitting coils and a driver circuit that supplies the charging current.

In one example, each planar power transmitting coil is formed by spiral winding a multi-strand wire. Each strand in the multi-strand wire may be electrically insulated from each other strand in the multi-strand wire.

In one example, the at least one substrate includes a PCB that has one or more holes provided therethrough. The one or more holes may be configured to conduct at least a portion of the airflow between channels in two substrates.

In some examples, the at least one substrate includes a coil substrate that has a plurality of cut-outs formed therein. The plurality of cut-outs may be configured to secure the plurality of planar power transmitting coils in a preconfigured three-dimensional arrangement. The preconfigured three-dimensional arrangement may provide a charging surface through a top surface of the coil substrate as a combination of power transfer areas of the plurality of planar power transmitting coils. A portion of the airflow may be directed toward the charging surface. The charging surface may include a porous material that passes some of the airflow that is directed toward the charging surface to the exterior of the wireless charging device. The preconfigured three-dimensional arrangement may provide planar power transmitting coils in a plurality of vertical planes.

In one example, the coil substrate is formed from a molded polymer and has one or more horizontal channels that interconnect with a plurality of vertical ducts. The one or more horizontal channels and the plurality of vertical ducts may be formed in the coil substrate during molding.

In one example, the coil substrate is formed by three-dimensional printing and includes interconnected horizontal channels and vertical ducts that are formed in the coil substrate during printing.

In one example, the coil substrate is formed from a polymer, acetate, vinyl, nitrile rubber, latex, extruded polystyrene foam and includes interconnected horizontal channels and vertical ducts that are formed in the coil substrate during printing formed milling, grinding, etching, abrading, chemical erosion or chemical dissolution.

Some implementation examples are described in the following numbered clauses:
1. A wireless charging device, comprising: at least one substrate having one or more channels formed therein, the one or more channels being configured to receive a flow of air and to conduct the flow of air through the at least one substrate to an outlet; a plurality of planar power transmitting coils supported by the at least one substrate, each planar power transmitting coil being formed as a spiral winding surrounding a power transfer area; and a driver circuit configured to provide a charging current to one or more of the plurality of planar power transmitting coils when a chargeable device is placed on or near the wireless charging device, wherein the one or more channels are configured to conduct the flow of air past or through the plurality of planar power transmitting coils and the driver circuit.
2. The wireless charging device as described in clause 1, wherein each planar power transmitting coil is formed by spiral winding a multi-strand wire, each strand in the multi-strand wire being electrically insulated from each other strand in the multi-strand wire.
3. The wireless charging device as described in clause 1 or clause 2, further comprising: a printed circuit board that has one or more holes provided therein, wherein the one or more holes are configured to conduct at least a portion of the flow of air between channels in two substrates.
4. The wireless charging device as described in any of clauses 1-3, wherein the at least one substrate comprises a coil substrate having a plurality of cut-outs formed therein, the plurality of cut-outs being configured to secure the plurality of planar power transmitting coils in a preconfigured three-dimensional arrangement.
5. The wireless charging device as described in clause 4, wherein the preconfigured three-dimensional arrangement provides a charging surface through a top surface of the coil substrate as a combination of power transfer areas of the plurality of planar power transmitting coils, and wherein a portion of the flow of air is directed toward the charging surface.
6. The wireless charging device as described in clause 5, wherein the charging surface comprises a porous material that passes some of the flow of air that is directed toward the charging surface to the exterior of the wireless charging device
7. The wireless charging device as described in clause 5 or clause 6, wherein the preconfigured three-dimensional arrangement provides planar power transmitting coils in a plurality of vertical planes.
8. The wireless charging device as described in any of clauses 5-7, wherein the coil substrate is formed from a molded polymer and has one or more horizontal channels that interconnect with a plurality of vertical ducts
9. The wireless charging device as described in clause 8, wherein the one or more horizontal channels and the plurality of vertical ducts are formed in the coil substrate during molding.
10. The wireless charging device as described in any of clauses 5-7, wherein the coil substrate is formed by three-dimensional printing and includes interconnected horizontal channels and vertical ducts that are formed in the coil substrate during printing.
11. The wireless charging device as described in any of clauses 5-7, wherein the coil substrate is formed from a polymer, acetate, vinyl, nitrile rubber, latex, extruded polystyrene foam and includes interconnected horizontal channels and vertical ducts that are formed in the coil substrate during printing formed milling, grinding, etching, abrading, chemical erosion or chemical dissolution.
12. The wireless charging device as described in any of clauses 1-11, wherein the receive a flow of air is received from an internal or external fan or impeller.
13. A method for operating a wireless charging device, comprising: providing a flow of air to a port of entry of the wireless charging device, the port of entry being fluidically coupled to one or more channels in at least one substrate of the wireless charging device, the one or more channels being configured to conduct the flow of air through the at least one substrate to a port of exit; providing a charging current to one or more planar power transmitting coils supported by the at least one substrate, each planar power transmitting coil being formed as a spiral winding surrounding a power transfer area; and directing the flow of air past or through the one or more planar power transmitting coils and a driver circuit that supplies the charging current.
14. The method as described in clause 13, wherein each planar power transmitting coil is formed by spiral winding a multi-strand wire, each strand in the multi-strand wire being electrically insulated from each other strand in the multi-strand wire.
15. The method as described in clause 13 or clause 14, wherein the at least one substrate comprises a printed circuit board that has one or more holes provided therethrough, wherein the one or more holes are configured to conduct at least a portion of the flow of air between channels in two substrates.
16. The method as described in any of clauses 13-15, wherein the at least one substrate comprises a coil substrate having a plurality of cut-outs formed therein, the plurality of cut-outs being configured to secure the one or more planar power transmitting coils in a preconfigured three-dimensional arrangement.
17. The method as described in clause 16, wherein the preconfigured three-dimensional arrangement provides a charging surface through a top surface of the coil substrate as a combination of power transfer areas of the one or more planar power transmitting coils, and wherein a portion of the flow of air is directed toward the charging surface.
18. The method as described in clause 17, wherein the charging surface comprises a porous material that passes some of the flow of air that is directed toward the charging surface to the exterior of the wireless charging device.
19. The method as described in clause 17 or clause 18, wherein the preconfigured three-dimensional arrangement provides planar power transmitting coils in a plurality of vertical planes.
20. The method as described in any of clauses 17-19, wherein the coil substrate is formed from a molded polymer and has one or more horizontal channels that interconnect with a plurality of vertical ducts.
21. The method as described in clause 20, wherein the one or more horizontal channels and the plurality of vertical ducts are formed in the coil substrate during molding.
22. The method as described in any of clauses 13-21, wherein the coil substrate is formed by three-dimensional printing and includes interconnected horizontal channels and vertical ducts that are formed in the coil substrate during printing.
23. The method as described in any of clauses 13-21, wherein the coil substrate is formed from a polymer, acetate, vinyl, nitrile rubber, latex, extruded polystyrene foam and includes interconnected horizontal channels and vertical ducts that are formed in the coil substrate during printing formed milling, grinding, etching, abrading, chemical erosion or chemical dissolution.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. A wireless charging device, comprising:
at least one substrate having one or more channels formed therein, the one or more channels being configured to receive a flow of air and to conduct the flow of air through the at least one substrate to an outlet;
a plurality of planar power transmitting coils supported by the at least one substrate, each planar power transmitting coil being formed as a spiral winding surrounding a power transfer area; and
a driver circuit configured to provide a charging current to one or more of the plurality of planar power transmitting coils when a chargeable device is placed on or near the wireless charging device,
wherein the one or more channels are configured to conduct the flow of air past or through the plurality of planar power transmitting coils and the driver circuit.

2. The wireless charging device of claim 1, wherein each planar power transmitting coil is formed by spiral winding a multi-strand wire, each strand in the multi-strand wire being electrically insulated from each other strand in the multi-strand wire.

3. The wireless charging device of claim 1, further comprising:
a printed circuit board that has one or more holes provided therein, wherein the one or more holes are configured to conduct at least a portion of the flow of air between channels in two substrates.

4. The wireless charging device of claim 1, wherein the at least one substrate comprises a coil substrate having a plurality of cut-outs formed therein, the plurality of cut-outs being configured to secure the plurality of planar power transmitting coils in a preconfigured three-dimensional arrangement.

5. The wireless charging device of claim 4, wherein the preconfigured three-dimensional arrangement provides a charging surface through a top surface of the coil substrate as a combination of power transfer areas of the plurality of planar power transmitting coils, and wherein a portion of the flow of air is directed toward the charging surface.

6. The wireless charging device of claim 5, wherein the charging surface comprises a porous material that passes some of the flow of air that is directed toward the charging surface to the exterior of the wireless charging device.

7. The wireless charging device of claim 5, wherein the preconfigured three-dimensional arrangement provides planar power transmitting coils in a plurality of vertical planes.

8. The wireless charging device of claim 5, wherein the coil substrate is formed from a molded polymer and has one or more horizontal channels that interconnect with a plurality of vertical ducts.

9. The wireless charging device of claim 8, wherein the one or more horizontal channels and the plurality of vertical ducts are formed in the coil substrate during molding.

10. The wireless charging device of claim 5, wherein the coil substrate is formed by three-dimensional printing and includes interconnected horizontal channels and vertical ducts that are formed in the coil substrate during printing.

11. The wireless charging device of claim 5, wherein the coil substrate is formed from a polymer, acetate, vinyl, nitrile rubber, latex, extruded polystyrene foam and includes interconnected horizontal channels and vertical ducts that are formed in the coil substrate during printing formed milling, grinding, etching, abrading, chemical erosion or chemical dissolution.

12. The wireless charging device of claim 5, wherein the receive a flow of air is received from an internal or external fan or impeller.

13. A method for operating a wireless charging device, comprising:
providing a flow of air to a port of entry of the wireless charging device, the port of entry being fluidically coupled to one or more channels in at least one substrate of the wireless charging device, the one or more channels being configured to conduct the flow of air through the at least one substrate to a port of exit;
providing a charging current to one or more planar power transmitting coils supported by the at least one substrate, each planar power transmitting coil being formed as a spiral winding surrounding a power transfer area; and
directing the flow of air past or through the one or more planar power transmitting coils and a driver circuit that supplies the charging current.

14. The method of claim 13, wherein each planar power transmitting coil is formed by spiral winding a multi-strand wire, each strand in the multi-strand wire being electrically insulated from each other strand in the multi-strand wire.

15. The method of claim 13, wherein the at least one substrate comprises a printed circuit board that has one or more holes provided therethrough, wherein the one or more holes are configured to conduct at least a portion of the flow of air between channels in two substrates.

16. The method of claim 13, wherein the at least one substrate comprises a coil substrate having a plurality of cut-outs formed therein, the plurality of cut-outs being configured to secure the one or more planar power transmitting coils in a preconfigured three-dimensional arrangement.

17. The method of claim 16, wherein the preconfigured three-dimensional arrangement provides a charging surface through a top surface of the coil substrate as a combination of power transfer areas of the one or more planar power transmitting coils, and wherein a portion of the flow of air is directed toward the charging surface.

18. The method of claim 17, wherein the charging surface comprises a porous material that passes some of the flow of air that is directed toward the charging surface to the exterior of the wireless charging device.

19. The method of claim 17, wherein the preconfigured three-dimensional arrangement provides planar power transmitting coils in a plurality of vertical planes.

20. The method of claim 17, wherein the coil substrate is formed from a molded polymer and has one or more horizontal channels that interconnect with a plurality of vertical ducts.

21. The method of claim 20, wherein the one or more horizontal channels and the plurality of vertical ducts are formed in the coil substrate during molding.

22. The method of claim 17, wherein the coil substrate is formed by three-dimensional printing and includes interconnected horizontal channels and vertical ducts that are formed in the coil substrate during printing.

23. The method of claim 17, wherein the coil substrate is formed from a polymer, acetate, vinyl, nitrile rubber, latex, extruded polystyrene foam and includes interconnected horizontal channels and vertical ducts that are formed in the coil substrate during printing formed milling, grinding, etching, abrading, chemical erosion or chemical dissolution.
